(19) United States
(12) Patent Application Publication
(10) Pub. No.: US 2026/0314237 A1
(43) Pub. Date: Oct. 8, 2026

(54) DISPLAY APPARATUS, METHOD OF MANUFACTURING THE SAME, AND ELECTRONIC APPARATUS INCLUDING THE DISPLAY APPARATUS

(71) Applicant: Samsung Display Co., Ltd., Yongin-si (KR)

(72) Inventor: Sungmin Huch, Yongin-si (KR)

(21) Appl. No.: 19/637,003

(22) Filed: Apr. 2, 2026

(30) Foreign Application Priority Data
Apr. 3, 2025 (KR) 10-2025-0043611

(51) Int. Cl. H10K 59/80; H10K 59/12; H10K 59/40

(52) U.S. Cl. CPC H10K 59/873; H10K 59/1201; H10K 59/40

(57) ABSTRACT

A display apparatus includes a substrate, a display element disposed on the substrate, and an encapsulation layer including a first inorganic encapsulation layer disposed on the display element, a second inorganic encapsulation layer disposed on the first inorganic encapsulation layer, and an organic encapsulation layer between the first inorganic encapsulation layer and the second inorganic encapsulation layer, wherein the second inorganic encapsulation layer includes a second-1 inorganic encapsulation layer disposed on the organic encapsulation layer, and a second-2 inorganic encapsulation layer disposed on the second-1 inorganic encapsulation layer, wherein the second-2 inorganic encapsulation layer includes silicon nitride, and a ratio of nitrogen to silicon in the second-2 inorganic encapsulation layer is about 0.75 to about 0.8.

This application is claims priority to Korean Patent Application No. 10-2025-0043611, filed on Apr. 3, 2025, and all the benefits accruing therefrom under 35 U.S.C. § 119, the content of which in its entirety is herein incorporated by reference.

### BACKGROUND

### 1. Field

Embodiments relate to a display apparatus, a method of manufacturing the display apparatus, and an electronic apparatus including the display apparatus, and more particularly, to a display apparatus having relatively low possibility of defect occurrence during a manufacturing process, a method of manufacturing the display apparatus, and an electronic apparatus including the display apparatus.

### 2. Description of the Related Art

Recently, the uses of display apparatuses continue to diversify. In addition, the thicknesses and weights of display apparatuses continue to decrease, and thus, the scope of their use continues to expand. As the range of uses of display apparatuses continues to become more diverse, various methods for designing the forms of display apparatuses are being studied.

Display apparatuses may display images by display elements each including a pixel electrode, an opposite electrode, and an emission layer between the pixel electrode and the opposite electrode. Because the display elements may be easily damaged by moisture or oxygen from the outside, an encapsulation layer may cover the display elements to protect them. This encapsulation layer may include inorganic encapsulation layers and an organic encapsulation layer between the inorganic encapsulation layers. The display apparatuses may further include touch sensors, so that information may be input from the outside by a user touching a display screen.

### SUMMARY

However, in existing display apparatuses, when the surface roughness of an inorganic encapsulation layer under an organic encapsulation layer is reduced in order to control the reflow of an organic encapsulation layer forming material during the formation of the organic encapsulation layer, the adhesive strength between the organic encapsulation layer and the inorganic encapsulation layer under the organic encapsulation layer may be reduced and the organic encapsulation layer may be separated from the inorganic encapsulation layer under the organic encapsulation layer during a process of manufacturing the display apparatuses.

Embodiments include a display apparatus having relatively low possibility of defect occurrence during a manufacturing process, a method of manufacturing the display apparatus, and an electronic apparatus. Embodiments set forth herein are examples, and embodiments of the disclosure are not limited thereto.

Additional features will be set forth in part in the description which follows and, in part, will be apparent from the description, or may be learned by practice of the presented embodiments of the disclosure.

In an embodiment of the disclosure, a display apparatus includes a substrate, a display element disposed on the substrate, and an encapsulation layer including a first inorganic encapsulation layer disposed on the display element, a second inorganic encapsulation layer disposed on the first inorganic encapsulation layer, and an organic encapsulation layer between the first inorganic encapsulation layer and the second inorganic encapsulation layer, wherein the second inorganic encapsulation layer includes a second-1 inorganic encapsulation layer disposed on the organic encapsulation layer, and a second-2 inorganic encapsulation layer disposed on the second-1 inorganic encapsulation layer, wherein the second-2 inorganic encapsulation layer includes silicon nitride, and a ratio of nitrogen to silicon in the second-2 inorganic encapsulation layer is about 0.75 to about 0.8.

In an embodiment, the second-2 inorganic encapsulation layer may have a compressive stress of about 50 megapascals (MPa) to about 90 MPa.

In an embodiment, the second-1 inorganic encapsulation layer may include silicon nitride, and a ratio of nitrogen to silicon in the second-1 inorganic encapsulation layer is less than the ratio of nitrogen to silicon in the second-2 inorganic encapsulation layer.

In an embodiment, a thickness of the second-1 inorganic encapsulation layer may be about 500 angstroms (Å) to about 1,000 Å, and a thickness of the second-2 inorganic encapsulation layer may be about 3,000 Å to about 12,000 Å.

In an embodiment, the first inorganic encapsulation layer may be in direct contact with the organic encapsulation layer, the second-1 inorganic encapsulation layer may be in direct contact with the organic encapsulation layer, and an adhesive strength between the first inorganic encapsulation layer and the organic encapsulation layer may be less than an adhesive strength between the second-1 inorganic encapsulation layer and the organic encapsulation layer.

In an embodiment, the display apparatus may include a touch sensor layer disposed on the encapsulation layer.

In an embodiment, the touch sensor layer may include a touch conductive layer and a touch insulating layer covering the touch conductive layer.

In an embodiment of the disclosure, a method of manufacturing a display apparatus includes forming a first inorganic encapsulation layer covering a display element on a substrate on which the display element is disposed, forming an organic encapsulation layer on the first inorganic encapsulation layer, forming a second-1 inorganic encapsulation layer on the organic encapsulation layer, and forming, on the second-1 inorganic encapsulation layer, a second-2 inorganic encapsulation layer including silicon nitride, wherein the forming the second-2 inorganic encapsulation layer includes forming the second-2 inorganic encapsulation layer by a first gas including silane (SiH₄) gas and ammonia (NH₃) gas, and a ratio of a flow rate of the ammonia (NH₃) gas to a flow rate of the silane (SiH₄) gas in the first gas is about 0.5 to about 0.6.

In an embodiment, a ratio of nitrogen to silicon in the second-2 inorganic encapsulation layer may be about 0.75 to about 0.8.

In an embodiment, the second-2 inorganic encapsulation layer may have a compressive stress of about 50 MPa to about 90 MPa.

In an embodiment, a ratio of nitrogen to silicon in the second-1 inorganic encapsulation layer may be less than a ratio of nitrogen to silicon in the second-2 inorganic encapsulation layer.

In an embodiment, a thickness of the second-1 inorganic encapsulation layer may be about 500 Å to about 1,000 Å, and a thickness of the second-2 inorganic encapsulation layer may be about 3,000 Å to about 12,000 Å.

In an embodiment, the forming the organic encapsulation layer may include forming the organic encapsulation layer directly on the first inorganic encapsulation layer, and the forming the second-1 inorganic encapsulation layer may include forming the second-1 inorganic encapsulation layer directly on the organic encapsulation layer, wherein an adhesive strength between the first inorganic encapsulation layer and the organic encapsulation layer may be less than an adhesive strength between the second-1 inorganic encapsulation layer and the organic encapsulation layer.

In an embodiment of the disclosure, an electronic apparatus includes a processor, and a display apparatus controlled by the processor, wherein the display apparatus includes a substrate, a display element disposed on the substrate, and an encapsulation layer including a first inorganic encapsulation layer disposed on the display element, a second inorganic encapsulation layer disposed on the first inorganic encapsulation layer, and an organic encapsulation layer between the first inorganic encapsulation layer and the second inorganic encapsulation layer, wherein the second inorganic encapsulation layer includes a second-1 inorganic encapsulation layer disposed on the organic encapsulation layer; and a second-2 inorganic encapsulation layer disposed on the second-1 inorganic encapsulation layer, and wherein the second-2 inorganic encapsulation layer includes silicon nitride, and a ratio of nitrogen to silicon in the second-2 inorganic encapsulation layer is about 0.75 to about 0.8.

In an embodiment, the second-2 inorganic encapsulation layer may have a compressive stress of about 50 MPa to about 90 MPa.

In an embodiment, the second-1 inorganic encapsulation layer may include silicon nitride, and a ratio of nitrogen to silicon in the second-1 inorganic encapsulation layer may be less than the ratio of nitrogen to silicon in the second-2 inorganic encapsulation layer.

In an embodiment, a thickness of the second-1 inorganic encapsulation layer may be about 500 Å to about 1,000 Å, and a thickness of the second-2 inorganic encapsulation layer may be about 3,000 Å to about 12,000 Å.

In an embodiment, the first inorganic encapsulation layer may be in direct contact with the organic encapsulation layer, the second-1 inorganic encapsulation layer may be in direct contact with the organic encapsulation layer, and an adhesive strength between the first inorganic encapsulation layer and the organic encapsulation layer may be less than an adhesive strength between the second-1 inorganic encapsulation layer and the organic encapsulation layer.

In an embodiment, the electronic apparatus may further include a touch sensor layer disposed on the encapsulation layer.

In an embodiment, the touch sensor layer may include a touch conductive layer and a touch insulating layer covering the touch conductive layer.

These and/or other features will become apparent and more readily appreciated from the following description of the embodiments, the accompanying drawings, and claims.

### BRIEF DESCRIPTION OF THE DRAWINGS

The above and other features and advantages of illustrative embodiments of the disclosure will be more apparent from the following description taken in conjunction with the accompanying drawings, in which:

FIG. 1A is a block diagram schematically illustrating an embodiment of an electronic apparatus;

FIG. 1B is a schematic diagram schematically illustrating embodiments of electronic apparatuses;

FIG. 2 is a plan view schematically illustrating an embodiment of a display apparatus;

FIG. 3 is a side view schematically illustrating an embodiment of a display apparatus;

FIG. 4 is a plan view schematically illustrating a portion of a touch sensor layer of FIG. 3;

FIG. 5 is an enlarged plan view of portion A of FIG. 4;

FIG. 6 is an equivalent circuit diagram of a pixel circuit included in the display apparatus of FIG. 2;

FIG. 7 is a cross-sectional view schematically illustrating a cross-section of the display apparatus taken along line I-I′ of FIG. 2;

FIG. 8 is a cross-sectional view schematically illustrating an apparatus for manufacturing a display apparatus used in a process of manufacturing the display apparatus of FIG. 7; and

FIGS. 9 to 12 are cross-sectional views schematically illustrating a part of a process of manufacturing the display apparatus of FIG. 7.

### DETAILED DESCRIPTION

Reference will now be made in detail to embodiments, illustrative embodiments of which are illustrated in the accompanying drawings, wherein like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and embodiments thereof will be illustrated in the drawings and will be described herein in detail. The effects and features of the disclosure and the accompanying methods thereof will become apparent from the following description of the embodiments, taken in conjunction with the accompanying drawings. However, the disclosure is not limited to the embodiments described below, and may be embodied in various modes.

In the specification, it will be understood that although the terms “first,” “second,” etc. may be used herein to describe various elements, these elements should not be limited by these terms. These elements are only used to distinguish one component from another component.

In the specification, the singular forms “a,” “an,” and “the” are intended to include the plural forms as well, unless the context clearly indicates otherwise.

In the specification, it will be understood that the terms “includes”, “has, “including”, and/or “having” used herein specify the presence of stated features or elements, but do not preclude the presence or addition of one or more other features or elements.

In the specification, the expression “A and/or B” indicates A, B, or A and B. Also, the expression “at least one of A and B” indicates A, B, or A and B.

In the specification, it will be understood that when a layer, region, or component is referred to as being “formed on” another layer, region, or component, it may be directly or indirectly formed on the other layer, region, or component. That is, for example, intervening layers, regions, or components may be present.

In the specification, when layers, regions, or components are connected to each other, the layers, the regions, or the components may be directly connected to each other, or another layer, another region, or another component may be interposed between the layers, the regions, or the components and thus the layers, the regions, or the components may be indirectly connected to each other. For example, in the specification, when layers, regions, or components are electrically connected to each other, the layers, the regions, or the components may be directly electrically connected to each other, or another layer, another region, or another component may be interposed between the layers, the regions, or the components and thus the layers, the regions, or the components may be indirectly electrically connected to each other.

In the specification, the x-axis, the y-axis and the z-axis are not limited to three axes of the rectangular coordinate system, and may be interpreted in a broader sense. In an embodiment, the x-axis, the y-axis, and the z-axis may be perpendicular to one another, or may represent different directions that are not perpendicular to one another, for example.

When an illustrative embodiment may be implemented differently, a predetermined process order may be performed differently from the described order. For example, two consecutively described processes may be performed substantially at the same time or performed in an order opposite to the described order.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within ±30%, 20%, 10%, 5% of the stated value, for example.

Hereinafter, embodiments will be described in detail with reference to the accompanying drawings, and in the description with reference to the drawings, the same or corresponding constituents are indicated by the same reference numerals and redundant descriptions thereof are omitted. Sizes of components in the drawings may be exaggerated for convenience of description. For example, since sizes and thicknesses of components in the drawings are arbitrarily illustrated for convenience of description, the following disclosure is not limited thereto.

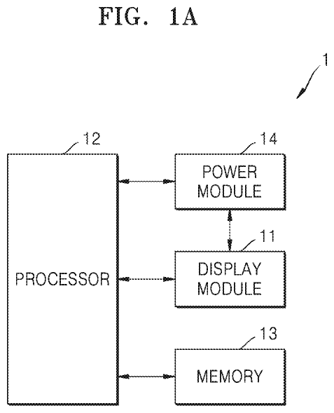

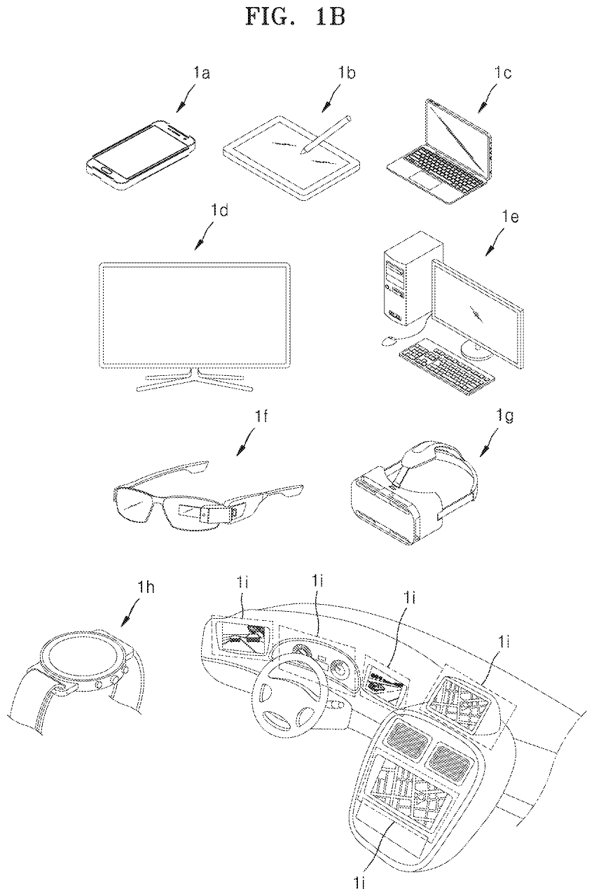

FIG. 1A is a block diagram schematically illustrating an embodiment of an electronic apparatus 1. The electronic apparatus 1 in the illustrated embodiment may further include modules having various additional functions in addition to the display module 11. In an embodiment, as illustrated in FIG. 1A, the electronic apparatus 1 in the illustrated embodiment may include the display module 11, a processor 12, a memory 13, and a power module 14, for example.

The processor 12 may control components of the electronic apparatus 1. The processor 12 may include at least one of a central processing unit (“CPU”), an application processor (“AP”), a graphic processing unit (“GPU”), a communication processor (“CP”), an image signal processor (“ISP”), and a controller.

The memory 13 may store data information desired for the operation of the processor 12 or the display module 11. When the processor 12 executes an application stored in the memory 13, a data signal and/or an input control signal for an image may be transmitted to the display module 11, and the display module 11 may process the received signal and output image information.

The power module 14 may include a power supply module, such as a power adapter or a battery device, and a power conversion module that converts the power supplied by the power supply module and generates power desired for the operation of the electronic apparatus 1.

FIG. 1B is a schematic diagram schematically illustrating embodiments of the electronic apparatus 1. Referring to FIG. 1B, the electronic apparatus 1 including the display module 11 may include not only an image display electronic apparatus, such as a smart phone 1a, a tablet personal computer 1b, a laptop 1c, a television (“TV”) 1d, and a desk monitor 1e, but also a wearable electronic apparatus including display modules, such as smart glasses 1f, a head-mounted display 1g, and a smart watch 1h, and a vehicle electronic apparatus 1i including display modules, such as a Center Information Display (“CID”) and a room mirror display, arranged on an instrument panel, center fascia, and dashboard of an automobile.

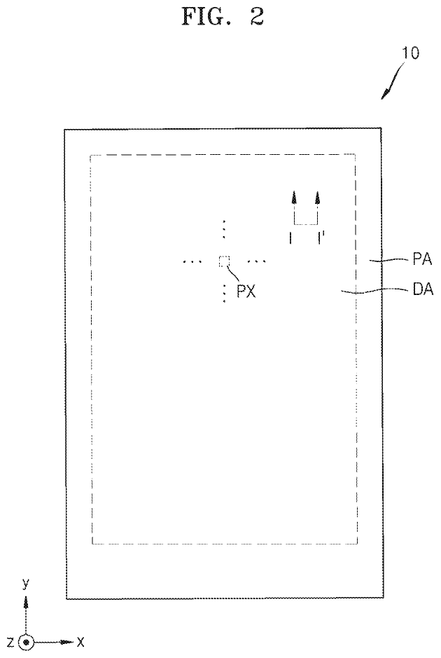

The display module 11 may include a display apparatus 10 (refer to FIG. 2). The display apparatus 10 may be applied to the various embodiments of the electronic apparatus 1. That is, the embodiments of the electronic apparatus 1 may each include the display apparatus 10, and may further include modules or devices having additional functions in addition to the display apparatus 10. In an embodiment, the electronic apparatus 1 may include the display apparatus 10, the processor 12, the memory 13, and the power module 14, and the display apparatus 10 may be controlled by the processor 12, for example. Hereinafter, the display apparatus 10 will be mainly described.

As illustrated in FIG. 2, the display apparatus 10 may include a display area DA in which a plurality of pixels PX are arranged, and a peripheral area PA disposed outside the display area DA. Specifically, the peripheral area PA may surround an entirety of the display area DA.

Each of the pixels PX of the display apparatus 10 is an area that may emit light of a predetermined color, and the display apparatus 10 may provide an image by light emitted from the pixels PX. In an embodiment, each pixel PX may emit red light, green light, or blue light, for example. The display area DA may have a polygonal shape including a quadrangle, as illustrated in FIG. 2. In an embodiment, the display area DA may have a quadrangular shape, e.g., rectangular shape with a horizontal length being less than a vertical length, a quadrangular shape, e.g., rectangular shape with a horizontal length being greater than a vertical length, or a square shape, for example. In an alternative embodiment, the display area DA may have various shapes, such as an ellipse or a circle.

The peripheral area PA may be a non-display area where pixels PX are not arranged. Drivers for providing electrical signals or power to the pixels PX may be arranged in the peripheral area PA. A plurality of pads (not shown), which are areas to which an electronic element, a printed circuit board, or the like may be electrically connected, may be arranged in the peripheral area PA. The plurality of pads may be arranged to be spaced apart from each other in the peripheral area PA and may be electrically connected to a printed circuit board or an integrated circuit element.

Hereinafter, an organic light-emitting display apparatus will be described in an embodiment of the display apparatus 10, but the display apparatus 10 is not limited thereto. In another embodiment, the display apparatus 10 may be an inorganic light-emitting display apparatus or an inorganic electroluminescence (“EL”) display apparatus, or may be a display apparatus such as a quantum dot light-emitting display apparatus. In an embodiment, an emission layer of a display element included in the display apparatus 10 may include an organic material or an inorganic material, for example. In addition, the display apparatus 10 may have an emission layer and a quantum dot layer disposed on the path of light emitted from the emission layer.

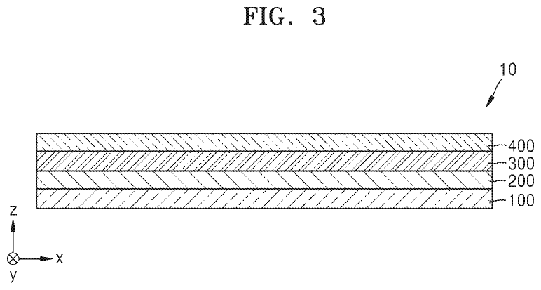

FIG. 3 is a side view schematically illustrating an embodiment of the display apparatus 10. The display apparatus 10 may include a substrate 100, a display element layer 200, an encapsulation layer 300, and a touch sensor layer 400.

The substrate 100 may include glass, metal, or a polymer resin. The substrate 100 needs to be flexible or bendable. In this case, the substrate 100 may include a polymer resin, such as polyethersulphone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multi-layer structure including two layers each including the polymer resin and a barrier layer including an inorganic material (e.g., silicon oxide (SiO_{X}), silicon nitride (SiN_{X}), or silicon oxynitride (SiO_{X}N_{Y})) disposed between the two layers, and various modifications are possible.

The display element layer 200 may be disposed on the substrate 100. The display element layer 200 may include a display element and may be a layer that displays an image. The display element may be provided in plural. That is, the display apparatus 10 may include a plurality of display elements, and the plurality of display elements may emit light. Accordingly, the display apparatus 10 may display an image through light emitted from the plurality of display elements.

Specifically, the display element layer 200 may include a display element and a pixel circuit electrically connected to the display element. In addition, the display element layer 200 may include scan lines, data lines, power lines, etc. connected to the pixel circuit, a scan driver for applying scan signals to the scan lines, and fan-out lines for connecting the data lines to a display driver.

In an embodiment, the display element may be an organic light-emitting diode including an organic emission layer. In an alternative embodiment, the display element may be a light-emitting diode. The size of the light-emitting diode may be micro-scale or nano-scale. In an embodiment, the light-emitting diode may be a micro light-emitting diode, for example. In an alternative embodiment, the light-emitting diode may be a nanorod light-emitting diode. The nanorod light-emitting diode may include gallium nitride (GaN). In an embodiment, a color conversion layer may be disposed on the nanorod light-emitting diode. The color conversion layer may include quantum dots. In an alternative embodiment, the display element may be a quantum dot light-emitting diode including a quantum dot emission layer. In an alternative embodiment, the display element may be an inorganic light-emitting diode including an inorganic semiconductor.

The encapsulation layer 300 may be disposed on the display element layer 200 to seal the display element. The encapsulation layer 300 may include at least one inorganic encapsulation layer and at least one organic encapsulation layer. Because the display element may be easily damaged by moisture or oxygen from the outside, the encapsulation layer 300 may cover the display element to protect the display element.

The touch sensor layer 400 may be disposed on the encapsulation layer 300. The touch sensor layer 400 may be a layer for sensing a user's touch input. The touch sensor layer 400 may sense a user's touch input, for example, in an electrostatic capacitance manner. However, the operation method of the touch sensor layer 400 is not particularly limited, and in an embodiment, the touch sensor layer 400 may sense an external input in an electromagnetic induction manner or a pressure detection manner. The touch sensor layer 400 may be provided with sensing electrodes to sense a touch input.

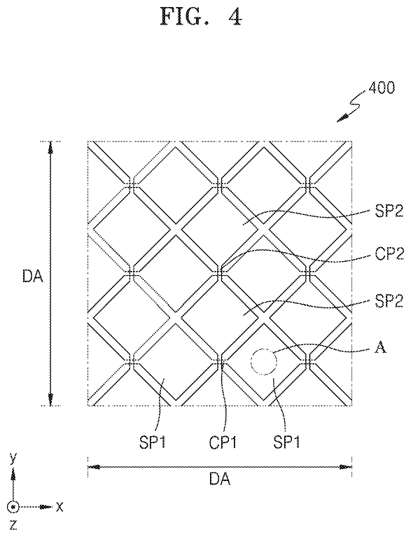

As illustrated in FIG. 4, which is a plan view schematically illustrating a portion of the touch sensor layer 400 of FIG. 3, the touch sensor layer 400 may include a plurality of first sensing electrodes SP1 arranged in a first direction (e.g., the x-axis direction) and a plurality of second sensing electrodes SP2 arranged in a second direction (e.g., the y-axis direction) intersecting the first direction. The first direction and the second direction may vertically intersect each other. That is, FIG. 4 schematically illustrates sensing electrodes included in the touch sensor layer 400.

Neighboring first sensing electrodes SP1 may be electrically connected to each other through a first connection electrode CP1. Neighboring second sensing electrodes SP2 may be electrically connected to each other through a second connection electrode CP2. The first sensing electrodes SP1 and the second sensing electrodes SP2 may include a conductive layer, and the conductive layer may include a conductive material. In an embodiment, the conductive layer may include molybdenum (Mo), aluminum (Al), copper (Cu), titanium (Ti), etc., and may have a single-layer or multi-layer structure including the aforementioned material, for example. In an embodiment, the conductive layer may have a structure in which a titanium (Ti) layer, an aluminum (Al) layer, and a titanium layer (Ti) are sequentially stacked, for example. The first connection electrodes CP1 and the second connection electrodes CP2 may each include the aforementioned conductive layer.

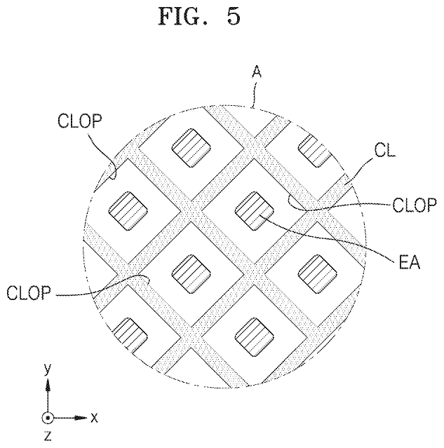

The sensing electrodes and the connection electrodes may each have a mesh structure including a plurality of openings. In an embodiment, as illustrated in FIG. 5, which is an enlarged plan view of portion A of FIG. 4, each first sensing electrode SP1 may be formed on a touch conductive layer CL, for example. The touch conductive layer CL may define each of a plurality of conductive layer openings CLOP. That is, a body portion of the touch conductive layer CL may surround each conductive layer opening CLOP. Accordingly, the touch conductive layer CL may form a mesh structure. In other words, the first sensing electrode SP1 may have a mesh structure including a plurality of openings. Similarly, each second sensing electrode SP2, each first connection electrode CP1, and each second connection electrode CP2 may also have a mesh structure. Each conductive layer opening CLOP of the touch conductive layer CL may overlap an emission area EA of each display element.

In FIG. 5, the emission area EA of the display element is illustrated as having a rhombus shape in a plan view, but the disclosure is not limited thereto. The emission area EA of the display element may have a polygonal shape, such as a triangle or a quadrangle, in a plan view. In an alternative embodiment, the emission area EA of the display element may have various shapes, such as an ellipse or a circle, in a plan view.

In FIG. 5, each of the conductive layer openings CLOP is illustrated as being entirely surrounded by the body portion of the touch conductive layer CL and not being spatially connected to each other, but the disclosure is not limited thereto. In an embodiment, at least one of the plurality of conductive layer openings CLOP may be partially surrounded by the body portion of the touch conductive layer CL, for example. In this case, neighboring conductive layer openings CLOP may be spatially connected to each other.

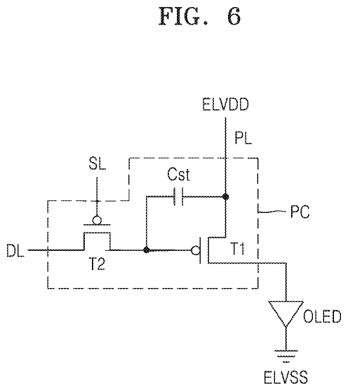

FIG. 6 is an equivalent circuit diagram of a pixel circuit PC included in the display apparatus 10 of FIG. 2. The pixel circuit PC may be electrically connected to a display element, and one display element may correspond to one pixel. In FIG. 6, an organic light-emitting diode OLED is illustrated as the display element. In an embodiment, the display element may emit red light, green light, or blue light.

The pixel circuit PC may include a first transistor T1, a second transistor T2, and a storage capacitor Cst. The second transistor T2 is a switching transistor and is connected to a scan line SL and a data line DL. The second transistor T2 may be turned on by a switching signal input from the scan line SL and transfer a data signal input from the data line DL to the first transistor T1. The storage capacitor Cst has one end electrically connected to the second transistor T2 and an opposite end electrically connected to a driving voltage line PL. The storage capacitor Cst may store a voltage corresponding to a difference between a voltage received from the second transistor T2 and a driving power supply voltage ELVDD supplied to the driving voltage line PL.

The first transistor T1 is a driving transistor and is connected to the driving voltage line PL and the storage capacitor Cst. The first transistor T1 may control the amount of driving current flowing from the driving voltage line PL to the organic light-emitting diode OLED in response to a voltage value stored in the storage capacitor Cst. The organic light-emitting diode OLED may emit light having a predetermined luminance by the driving current. An opposite electrode of the organic light-emitting diode OLED may receive an electrode power supply voltage ELVSS.

Although FIG. 6 illustrates that the pixel circuit PC includes two transistors and one storage capacitor, the disclosure is not limited thereto. In an embodiment, the number of transistors or storage capacitors may be variously changed depending on the design of the pixel circuit PC, for example.

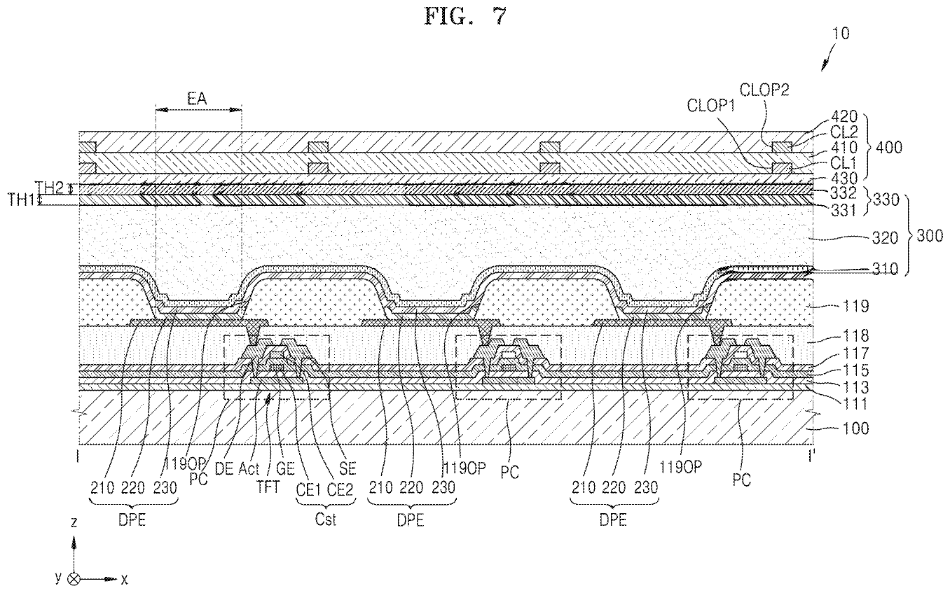

FIG. 7 is a cross-sectional view schematically illustrating a cross-section of the display apparatus 10 taken along line I-I′ of FIG. 2. As will be recognized by those skilled in the art, the display apparatus 10 may further include various other components in addition to the configuration illustrated in FIG. 7.

As illustrated in FIG. 7, the display apparatus 10 includes a substrate 100. Because the display apparatus 10 includes the substrate 100, it may be said that the substrate 100 has a display area DA and a peripheral area PA. Hereinafter, for convenience, the substrate 100 will be described as having the display area DA and the peripheral area PA.

A display element DPE and a pixel circuit PC to which the display element DPE is electrically connected may be arranged on the display area DA of the substrate 100. The fact that the display element DPE is electrically connected to the pixel circuit PC may be understood as meaning that a pixel electrode 210 included in the display element DPE is electrically connected to a transistor TFT of the pixel circuit PC.

The display element DPE and the pixel circuit PC electrically connected to the display element DPE may be arranged on the substrate 100. Specifically, a plurality of pixel circuits PC may be arranged on the substrate 100. The plurality of pixel circuits PC may be electrically connected to a plurality of display elements DPE, respectively. Because the structures of the plurality of pixel circuits PC are the same and the structures of the plurality of display elements DPE are the same, the following description will focus on one pixel circuit PC and one display element DPE.

The pixel circuit PC may be disposed on the substrate 100. The pixel circuit PC includes a plurality of transistors TFT and a storage capacitor Cst. For convenience of illustration, one transistor TFT is illustrated in FIG. 7, and the transistor TFT may correspond to the first transistor T1 (refer to FIG. 6) described above.

A buffer layer 111 including an inorganic material, such as silicon oxide (SiO_{X}), silicon nitride (SiN_{X}), and/or silicon oxynitride (SiO_{X}N_{Y}), may be disposed between the transistor TFT and the substrate 100. The buffer layer 111 may increase the smoothness of the upper surface of the substrate 100 or prevent or reduce impurities from the substrate 100 or the like from penetrating into a semiconductor layer Act of the transistor TFT.

As illustrated in FIG. 7, the transistor TFT may include the semiconductor layer Act including amorphous silicon, polycrystalline silicon, an organic semiconductor material, or an oxide semiconductor material. The transistor TFT may include a gate electrode GE, a source electrode SE, and/or a drain electrode DE. The gate electrode GE may include various conductive materials and have various layered structures. In an embodiment, the gate electrode GE may include a Mo layer and an Al layer, for example. In an alternative embodiment, the gate electrode GE may include a TiN_{X} layer, an Al layer, and/or a Ti layer. The source electrode SE and the drain electrode DE may also include various conductive materials and have various layered structures. In an embodiment, each of the source electrode SE and the drain electrode DE may include a Ti layer, an Al layer, and/or a Cu layer, for example.

In order to secure insulation between the semiconductor layer Act and the gate electrode GE, a gate insulating layer 113 including an inorganic material, such as silicon oxide (SiO_{X}), silicon nitride (SiN_{X}), and/or silicon oxynitride (SiO_{X}N_{Y}), may be disposed between the semiconductor layer Act and the gate electrode GE. In FIG. 7, the gate insulating layer 113 is illustrated as having a shape corresponding to the entirety of the surface of the substrate 100 and having a structure in which contact holes are formed in preset portions, but the disclosure is not limited thereto. In an embodiment, the gate insulating layer 113 may be patterned to have the same shape as that of the gate electrode GE, for example.

In addition, a first inter-insulating layer 115 including an inorganic insulating material, such as silicon oxide (SiO_{X}), silicon nitride (SiN_{X}), and/or silicon oxynitride (SiO_{X}N_{Y}), may be disposed on the gate electrode GE. The first inter-insulating layer 115 may have a single-layer or multi-layer structure including the aforementioned material. The insulating layer including the inorganic insulating material may be formed through a method such as chemical vapor deposition. This also applies to the embodiments and modifications thereof described below.

The storage capacitor Cst may include a first capacitor electrode CE1 and a second capacitor electrode CE2 that overlap each other with the first inter-insulating layer 115 therebetween. The storage capacitor Cst may overlap the transistor TFT. In this regard, FIG. 7 illustrates that the gate electrode GE of the transistor TFT is the first capacitor electrode CE1 of the storage capacitor Cst, but the disclosure is not limited thereto. In an embodiment, the storage capacitor Cst may not overlap the transistor TFT, for example. The second capacitor electrode CE2 of the storage capacitor Cst may include a conductive material including molybdenum (Mo), aluminum (Al), copper (Cu), or titanium (Ti), and may have a multi-layer or single-layer structure including the aforementioned material.

A second inter-insulating layer 117 including an inorganic material, such as silicon oxide (SiO_{X}), silicon nitride (SiN_{X}), and/or silicon oxynitride (SiO_{X}N_{Y}), may be disposed on the second capacitor electrode CE2 of the storage capacitor Cst. The second inter-insulating layer 117 may have a single-layer or multi-layer structure including the aforementioned material.

The source electrode SE and the drain electrode DE may be arranged on the second inter-insulating layer 117. The source electrode SE and the drain electrode DE may each include a material having excellent conductivity. The source electrode SE and the drain electrode DE may each include a conductive material including molybdenum (Mo), aluminum (Al), copper (Cu), or titanium (Ti), and may each have a multi-layer or single-layer structure including the aforementioned material. In an embodiment, the source electrode SE and the drain electrode DE may each have a multi-layer structure including Ti/Al/Ti layers, for example.

However, the disclosure is not limited thereto. In an embodiment, the transistor TFT may have only one of the source electrode SE and the drain electrode DE, or may not have both of them, for example. In an embodiment, one transistor TFT may not have a drain electrode DE, and another transistor TFT connected to the transistor TFT may not have a source electrode SE, and the semiconductor layers Act of the two transistors may be connected to each other, for example. This connection structure may have the same effect as when one transistor TFT has a source electrode SE, another transistor TFT has a drain electrode DE, and the source electrode SE of one transistor TFT is connected to the drain electrode DE of a remaining (the other) transistor TFT.

As illustrated in FIG. 7, an organic insulating layer 118 may be disposed to cover the transistor TFT and the storage capacitor Cst. The organic insulating layer 118 may include an organic insulating material. In an embodiment, the organic insulating layer 118 may include photoresist, benzocyclobutene (“BCB”), polyimide, hexamethyldisiloxane (“HMDSO”), polymethylmethacrylate (“PMMA”), polystyrene, a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, any combinations thereof, or the like, for example. Although not shown in FIG. 7, a third inter-insulating layer (not shown) may be further disposed under the organic insulating layer 118. The third inter-insulating layer may include an inorganic insulating material, such as silicon oxide (SiO_{X}), silicon nitride (SiN_{X}), and/or silicon oxynitride (SiO_{X}N_{Y}).

The display element DPE may be disposed on the organic insulating layer 118. In an embodiment, the display element DPE may be an organic light-emitting diode, for example. The display element DPE may include a pixel electrode 210, an emission layer 220, and an opposite electrode 230. The opposite electrode 230 may be integrally provided across the entirety of the surface of the display apparatus 10, and thus may be commonly provided for a plurality of display elements DPE.

The pixel electrode 210 includes a light-transmitting conductive layer including or consisting of a light-transmitting conductive oxide, such as indium tin oxide (“ITO”), In₂O₃, or indium zinc oxide (“IZO”), and a reflective layer including or consisting of a metal, such as Al or Ag. In an embodiment, the pixel electrode 210 may have a three-layer structure including ITO/Ag/ITO layers, for example. The pixel electrode 210 may be electrically connected to the transistor TFT by contacting one of the source electrode SE and the drain electrode DE, as illustrated in FIG. 7. Specifically, the pixel electrode 210 may contact one of the source electrode SE and the drain electrode DE through a contact hole defined in the organic insulating layer 118.

A pixel-defining layer 119 may be disposed on the organic insulating layer 118. As described above, a pixel opening 119OP may be defined in the pixel-defining layer 119. The pixel opening 119OP may expose a central portion of the pixel electrode 210 of the display element DPE, and at least a portion of the emission layer 220 of the display element DPE may be disposed within the pixel opening 119OP. That is, the emission area EA of the display element DPE may be defined by the pixel opening 119OP. In addition, as shown in FIG. 7, the pixel-defining layer 119 may increase the distance between the edge of the pixel electrode 210 and the opposite electrode 230 above the pixel electrode 210. As a result, arcs, etc. may be prevented from occurring at the edge of the pixel electrode 210. The pixel-defining layer 119 may include an organic material, such as polyimide or hexamethyldisiloxane (“HMDSO”).

The opposite electrode 230 may be disposed on the pixel electrode 210. The opposite electrode 230 may be integrally provided across the plurality of display elements DPE. Therefore, the opposite electrode 230 may be disposed on a plurality of pixel electrodes 210. The opposite electrode 230 may include a light-transmitting conductive layer including or consisting of ITO, In₂O₃, or IZO, and may also include a semi-transmissive layer including a metal, such as Al or Ag. In an embodiment, the opposite electrode 230 may be a semi-transmissive layer including Mg or Ag, for example.

The emission layer 220 capable of emitting light may be disposed between the pixel electrode 210 and the opposite electrode 230. The emission layer 220 may emit red light, green light or blue light. The emission layer 220 may include a polymer or low-molecular organic material capable of emitting light of a predetermined color (red, green, or blue). In an embodiment, the emission layer 220 may include a polymer material, such as a polyphenylene vinylene (“PPV”)-based material and a polyfluorene-based material, for example. This emission layer 220 may be formed by screen printing, inkjet printing, laser induced thermal imaging (“LITI”), etc. However, the disclosure is not limited thereto.

In an embodiment, a functional layer (not shown) may be disposed below and above the emission layer 220. The functional layer may include a hole injection layer (“HIL”), a hole transport layer (“HTL”), an electron transport layer (“ETL”), and/or an electron injection layer (“EIL”). The functional layer may be integrally formed (or unitary) across the plurality of pixel electrodes 210, or may be patterned to correspond to each of the plurality of pixel electrodes 210.

An encapsulation layer 300 may be disposed on the display element DPE. Specifically, the encapsulation layer 300 may be disposed on the opposite electrode 230. That is, because the display element DPE may be easily damaged by moisture or oxygen from the outside, the encapsulation layer 300 may cover the display element DPE to protect the display element DPE.

The encapsulation layer 300 may include a first inorganic encapsulation layer 310, an organic encapsulation layer 320, and a second inorganic encapsulation layer 330, as illustrated in FIG. 7. The second inorganic encapsulation layer 330 may include a second-1 inorganic encapsulation layer 331 and a second-2 inorganic encapsulation layer 332. Specifically, the encapsulation layer 300 including the first inorganic encapsulation layer 310, the second inorganic encapsulation layer 330, and the organic encapsulation layer 320 therebetween may be arranged on the opposite electrode 230. That is, the first inorganic encapsulation layer 310, the organic encapsulation layer 320, the second-1 inorganic encapsulation layer 331, and the second-2 inorganic encapsulation layer 332 may be sequentially stacked in a thickness direction (e.g., the z-axis direction) of the substrate 100.

The first inorganic encapsulation layer 310 may cover the opposite electrode 230. The first inorganic encapsulation layer 310 may be disposed on the opposite electrode 230, and may be in direct contact with the opposite electrode 230. The first inorganic encapsulation layer 310 may include at least one of silicon oxide (SiO_{X}), silicon nitride (SiN_{X}), and silicon oxynitride (SiO_{X}N_{Y}). Other layers, such as a capping layer, may be arranged between the first inorganic encapsulation layer 310 and the opposite electrode 230 as desired. Because the first inorganic encapsulation layer 310 is formed along the structure thereunder, the upper surface of the first inorganic encapsulation layer 310 may not be flat as shown in FIG. 7.

The organic encapsulation layer 320 may cover the first inorganic encapsulation layer 310. The organic encapsulation layer 320 may be disposed on the first inorganic encapsulation layer 310, and may be in direct contact with the first inorganic encapsulation layer 310. In other words, the organic encapsulation layer 320 may be disposed between the first inorganic encapsulation layer 310 and the second inorganic encapsulation layer 330. The organic encapsulation layer 320 may have a substantially flat upper surface, unlike the first inorganic encapsulation layer 310. The organic encapsulation layer 320 may include one or more materials selected from the group consisting of polyethyleneterephthalate, polyethylenenaphthalate, polycarbonate, polyimide, polyethylenesulfonate, polyoxymethylene, polyarylate, and hexamethyldisiloxane.

The second inorganic encapsulation layer 330 may cover the organic encapsulation layer 320. The second inorganic encapsulation layer 330 may be disposed on the organic encapsulation layer 320, and may be in direct contact with the organic encapsulation layer 320. Specifically, the second-1 inorganic encapsulation layer 331 may be disposed on the organic encapsulation layer 320, and the second-2 inorganic encapsulation layer 332 may be disposed on the second-1 inorganic encapsulation layer 331. The second-1 inorganic encapsulation layer 331 may be in direct contact with the organic encapsulation layer 320, and the second-2 inorganic encapsulation layer 332 may be in direct contact with the second-1 inorganic encapsulation layer 331.

The second inorganic encapsulation layer 330 may include silicon nitride (SiN_{X}).

Specifically, each of the second-1 inorganic encapsulation layer 331 and the second-2 inorganic encapsulation layer 332 may include silicon nitride (SiN_{X}). The ratio of nitrogen (N) to silicon (Si) in the second-1 inorganic encapsulation layer 331 and the ratio of nitrogen (N) to silicon (Si) in the second-2 inorganic encapsulation layer 332 may be different. Detailed descriptions of the second-1 inorganic encapsulation layer 331 and the second-2 inorganic encapsulation layer 332 will be described below.

Because the encapsulation layer 300 includes the first inorganic encapsulation layer 310, the organic encapsulation layer 320, and the second inorganic encapsulation layer 330, even when a crack occurs within the encapsulation layer 300 through this multi-layer structure, the crack may be prevented from being connected between the first inorganic encapsulation layer 310 and the organic encapsulation layer 320 or between the organic encapsulation layer 320 and the second inorganic encapsulation layer 330. Therefore, it is possible to prevent or reduce the formation of a path through which moisture or oxygen from the outside may penetrate into the display apparatus 10.

The first inorganic encapsulation layer 310 may have a relatively small surface roughness. Because the first inorganic encapsulation layer 310 has a relatively small surface roughness, the adhesive strength between the first inorganic encapsulation layer 310 and the organic encapsulation layer 320 may be low. Specifically, the adhesive strength between the first inorganic encapsulation layer 310 and the organic encapsulation layer 320 may be less than the adhesive strength between the second-1 inorganic encapsulation layer 331 and the organic encapsulation layer 320.

In the specification, the surface roughness of the first inorganic encapsulation layer 310 refers to the roughness of the upper surface of the first inorganic encapsulation layer 310. That is, the surface roughness of the first inorganic encapsulation layer 310 refers to the roughness of one side of the first inorganic encapsulation layer 310 facing opposite to the substrate 100. In other words, the surface roughness of the first inorganic encapsulation layer 310 refers to the roughness of one side of the first inorganic encapsulation layer 310 that contacts the organic encapsulation layer 320. The surface roughness may be measured using an atomic force microscopy (“AFM”) on the surface of a sample having a predetermined area. Surface roughness may be defined as arithmetic mean roughness, root mean square average roughness, or maximum height roughness, depending on measurement methods.

Specifically, the surface roughness of the first inorganic encapsulation layer 310 may be about 2 nanometers (nm) to about 6 nm based on the arithmetic mean roughness. In an embodiment, the surface roughness of the first inorganic encapsulation layer 310 may be 4 nm based on the arithmetic mean roughness, for example. Accordingly, the adhesive strength between the first inorganic encapsulation layer 310 and the organic encapsulation layer 320 may be about 1.1 gram-force per inch (gf/inch) to about 1.2 gf/inch. In an embodiment, the adhesive strength between the first inorganic encapsulation layer 310 and the organic encapsulation layer 320 may be 1.17 gf/inch, for example.

As described above, the organic encapsulation layer 320 may be disposed on the first inorganic encapsulation layer 310, and may cover the upper surface of the first inorganic encapsulation layer 310. The organic encapsulation layer 320 may be formed by applying an organic encapsulation layer forming material for forming the organic encapsulation layer 320 onto the upper surface of the first inorganic encapsulation layer 310 and then curing the organic encapsulation layer forming material. The surface roughness of the first inorganic encapsulation layer 310 may affect the formation of the organic encapsulation layer 320.

That is, when the surface roughness of the first inorganic encapsulation layer 310 is within the range described above, the organic encapsulation layer forming material applied on the first inorganic encapsulation layer 310 may have appropriate flow characteristics or reflow characteristics. Accordingly, when the organic encapsulation layer forming material applied on the first inorganic encapsulation layer 310 is cured, the organic encapsulation layer forming material does not spread excessively, and thus, the organic encapsulation layer forming material may be controlled so that the organic encapsulation layer forming material is disposed only on the first inorganic encapsulation layer 310.

In contrast, when the surface roughness of the first inorganic encapsulation layer 310 exceeds the range described above, when the organic encapsulation layer forming material applied on the first inorganic encapsulation layer 310 is cured, the flow characteristics or reflow characteristics of the organic encapsulation layer forming material may excessively increase, and thus, the organic encapsulation layer forming material may spread excessively. Accordingly, the organic encapsulation layer forming material may not be controlled so that the organic encapsulation layer forming material is disposed only on the first inorganic encapsulation layer 310.

When the surface roughness of the first inorganic encapsulation layer 310 is less than the range described above, the adhesive strength between the first inorganic encapsulation layer 310 and the organic encapsulation layer 320 arranged on the first inorganic encapsulation layer 310 may be excessively low. Accordingly, the organic encapsulation layer 320 may be easily separated from the first inorganic encapsulation layer 310.

A touch sensor layer 400 may be disposed on the encapsulation layer 300. The touch sensor layer 400 may include a touch conductive layer and a touch insulating layer covering the touch conductive layer. Specifically, the touch sensor layer 400 may include a first touch conductive layer CL1, a first touch insulating layer 410, a second touch conductive layer CL2, and a second touch insulating layer 420.

The first touch conductive layer CL1 may be disposed on the second inorganic encapsulation layer 330. In an embodiment, the first touch conductive layer CL1 may overlap the pixel-defining layer 119. The first touch conductive layer CL1 may not overlap the pixel opening 119OP of the pixel-defining layer 119. That is, the first touch conductive layer CL1 may define a first conductive layer opening CLOP1 that overlaps the emission area EA of the display element DPE. Accordingly, the first touch conductive layer CL1 may have a mesh structure so that light emitted from the display element DPE may pass therethrough.

The first touch conductive layer CL1 may include a conductive material. In an embodiment, the first touch conductive layer CL1 may include molybdenum (Mo), aluminum (Al), copper (Cu), titanium (Ti), or the like and may have a single-layer or multi-layer structure including the aforementioned material, for example. In an embodiment, the first touch conductive layer CL1 may have a structure in which a titanium (Ti) layer, an aluminum (Al) layer, and a titanium (Ti) layer are sequentially stacked, for example.

The first touch insulating layer 410 may cover the first touch conductive layer CL1. That is, the first touch insulating layer 410 may be a touch insulating layer covering the touch conductive layer. The first touch insulating layer 410 may have a single-layer or multi-layer structure including an inorganic insulating material, such as silicon oxide (SiO_{X}), silicon nitride (SiN_{X}), and/or silicon oxynitride (SiO_{X}N_{Y}). In an embodiment, the first touch insulating layer 410 may include an organic insulating material.

The second touch conductive layer CL2 may be disposed on the first touch insulating layer 410. In an embodiment, the second touch conductive layer CL2 may overlap the pixel-defining layer 119. The second touch conductive layer CL2 may not overlap the pixel opening 119OP of the pixel-defining layer 119. That is, the second touch conductive layer CL2 may define a second conductive layer opening CLOP2 that overlaps the emission area EA of the display element DPE. Accordingly, the second touch conductive layer CL2 may have a mesh structure so that light emitted from the display element DPE may pass therethrough.

The second touch conductive layer CL2 may include a conductive material. In an embodiment, the second touch conductive layer CL2 may include molybdenum (Mo), aluminum (Al), copper (Cu), titanium (Ti), or the like and may have a single-layer or multi-layer structure including the aforementioned material, for example. In an embodiment, the second touch conductive layer CL2 may have a structure in which a titanium (Ti) layer, an aluminum (Al) layer, and a titanium (Ti) layer are sequentially stacked, for example.

In an embodiment, the second touch conductive layer CL2 may be electrically connected to the first touch conductive layer CL1 through a contact hole defined in the first touch insulating layer 410. Referring to FIG. 4, each of the first sensing electrode SP1 and the second sensing electrode SP2 described above may be formed as a two-layer structure of the first touch conductive layer CL1 and the second touch conductive layer CL2 that are electrically connected to each other. In other words, the touch conductive layer CL of FIG. 4 may include the first touch conductive layer CL1 and the second touch conductive layer CL2, and the conductive layer opening CLOP of FIG. 4 may include the first conductive layer opening CLOP1 and the second conductive layer opening CLOP2.

The second touch insulating layer 420 may cover the second touch conductive layer CL2. That is, the second touch insulating layer 420 may be a touch insulating layer covering the touch conductive layer. The second touch insulating layer 420 may have a single-layer or multi-layer structure including an inorganic insulating material, such as silicon oxide (SiO_{X}), silicon nitride (SiN_{X}), and/or silicon oxynitride (SiO_{X}N_{Y}). In an embodiment, the second touch insulating layer 420 may include an organic insulating material.

The touch sensor layer 400 may further include a touch buffer layer 430. The touch buffer layer 430 may be disposed between the encapsulation layer 300 and the first touch conductive layer CL1. Specifically, the touch buffer layer 430 may be disposed on the second inorganic encapsulation layer 330, and the first touch conductive layer CL1 may be disposed on the touch buffer layer 430. The touch buffer layer 430 may prevent damage to the encapsulation layer 300 and may block interference signals that may occur when the touch sensor layer 400 is driven. In an embodiment, the touch buffer layer 430 may have a single-layer or multi-layer structure including an inorganic insulating material, such as silicon oxide (SiO_{X}), silicon nitride (SiN_{X}), and/or silicon oxynitride (SiO_{X}N_{Y}). In an embodiment, the touch buffer layer 430 may include an organic material.

As described above, each of the second-1 inorganic encapsulation layer 331 and the second-2 inorganic encapsulation layer 332 may include silicon nitride (SiN_{X}), and the ratio of nitrogen (N) to silicon (Si) in the second-1 inorganic encapsulation layer 331 and the ratio of nitrogen (N) to silicon (Si) in the second-2 inorganic encapsulation layer 332 may be different. In the specification, the ratio of nitrogen (N) to silicon (Si) refers to the ratio of nitrogen (N) in silicon nitride (SiN_{X}) to silicon (Si) in silicon nitride (SiN_{X}). In other words, the ratio of nitrogen (N) to silicon (Si) refers to the number of nitrogen (N) in silicon nitride (SiN_{X}) when the number of silicon (Si) in silicon nitride (SiN_{X}) is 1.

Silicon nitride (SiN_{X}) is composed of silicon (Si) and nitrogen (N), and the ratio of nitrogen (N) to silicon (Si) in silicon nitride (SiN_{X}) may vary depending on formation conditions during the formation of silicon nitride (SiN_{X}). The ratio of nitrogen (N) to silicon (Si) in silicon nitride (SiN_{X}) may affect the characteristics of silicon nitride (SiN_{X}). In an embodiment, when the ratio of nitrogen (N) to silicon (Si) in silicon nitride (SiN_{X}) is low, some of the silicon (Si) atoms may have dangling bonds, for example.

Accordingly, a layer including or consisting of silicon nitride (SiN_{X}) having a relatively low ratio of nitrogen (N) to silicon (Si) may be porous. Accordingly, the layer including or consisting of silicon nitride (SiN_{X}) having a relatively low ratio of nitrogen (N) to silicon (Si) may have a relatively low density. In contrast, a layer including or consisting of silicon nitride (SiN_{X}) having a relatively high ratio of nitrogen (N) to silicon (Si) may be dense. Accordingly, the layer including or consisting of silicon nitride (SiN_{X}) having a relatively high ratio of nitrogen (N) to silicon (Si) may have a relatively high density.

When an inorganic insulating layer is formed by a method such as chemical vapor deposition (“CVD”) or a metal layer is formed by a method such as sputtering, the formed inorganic insulating layer and metal layer may have residual stress. The residual stress is a unique characteristic of the inorganic insulating layer, etc., and does not change even when an external force is applied to the inorganic insulating layer, etc. The inorganic insulating layer, etc. may have tensile stress or compressive stress as the residual stress. Specifically, the inorganic insulating layer may have compressive stress as the residual stress. In an embodiment, the second-1 inorganic encapsulation layer 331 and the second-2 inorganic encapsulation layer 332 may have compressive stress as the residual stress, for example.

Because a layer including or consisting of silicon nitride (SiN_{X}) having a relatively low ratio of nitrogen (N) to silicon (Si) is porous, the layer including or consisting of silicon nitride (SiN_{X}) having a relatively low ratio of nitrogen (N) to silicon (Si) may have relatively low compressive stress. In contrast, because a layer including or consisting of silicon nitride (SiN_{X}) having a relatively high ratio of nitrogen (N) to silicon (Si) is dense, the layer including or consisting of silicon nitride (SiN_{X}) having a relatively high ratio of nitrogen (N) to silicon (Si) may have relatively high compressive stress.

In an embodiment, the ratio of nitrogen (N) to silicon (Si) in the second-1 inorganic encapsulation layer 331 may be less than the ratio of nitrogen (N) to silicon (Si) in the second-2 inorganic encapsulation layer 332. Specifically, the ratio of nitrogen (N) to silicon (Si) in the second-1 inorganic encapsulation layer 331 may be about 0.65 to about 0.7. In an embodiment, the ratio of nitrogen (N) to silicon (Si) in the second-1 inorganic encapsulation layer 331 may be 0.67, for example. Accordingly, the density of the second-1 inorganic encapsulation layer 331 may be lower than the density of the second-2 inorganic encapsulation layer 332. The thickness TH1 of the second-1 inorganic encapsulation layer 331 may be about 500 angstroms (Å) to about 1,000 Å.

Because the second-1 inorganic encapsulation layer 331 has a density that is lower than that of the second-2 inorganic encapsulation layer 332, the voltage for forming the second-1 inorganic encapsulation layer 331 may be lower than the voltage for forming the second-2 inorganic encapsulation layer 332. When the second-2 inorganic encapsulation layer 332 is formed directly on the organic encapsulation layer 320, outgassing may occur in the organic encapsulation layer 320 when the second-2 inorganic encapsulation layer 332 is formed. Therefore, by forming a second-1 inorganic encapsulation layer 331, which has a density that is lower than that of the second-2 inorganic encapsulation layer 332, on the organic encapsulation layer 320 to have a relatively small thickness and then forming the second-2 inorganic encapsulation layer 332 on the second-1 inorganic encapsulation layer 331, the outgassing occurring in the organic encapsulation layer 320 may be reduced.

In an embodiment, the ratio of nitrogen (N) to silicon (Si) in the second-2 inorganic encapsulation layer 332 may be about 0.75 to about 0.8. The thickness TH2 of the second-2 inorganic encapsulation layer 332 may be about 3,000 Å to about 12,000 Å. Accordingly, the second-2 inorganic encapsulation layer 332 may have a compressive stress of about 50 megapascals (MPa) to about 90 MPa.

When the ratio of nitrogen (N) to silicon (Si) in the second-2 inorganic encapsulation layer 332 exceeds 0.8, the second-2 inorganic encapsulation layer 332 may have a compressive stress exceeding 90 MPa. When the second-2 inorganic encapsulation layer 332 has a compressive stress exceeding 90 MPa, the compressive stress applied per unit area of the display apparatus 10 may be excessively large, and thus, the organic encapsulation layer 320 may be easily separated from the first inorganic encapsulation layer 310 during the process of manufacturing the display apparatus 10.

Unlike the first inorganic encapsulation layer 310 having a relatively small surface roughness, which results in relatively low adhesive strength between the first inorganic encapsulation layer 310 and the organic encapsulation layer 320, the adhesive strength between the second-1 inorganic encapsulation layer 331 and the organic encapsulation layer 320 may be sufficiently high. Specifically, the adhesive strength between the second-1 inorganic encapsulation layer 331 and the organic encapsulation layer 320 may be about 1.7 gf/inch to about 1.8 gf/inch. In an embodiment, the adhesive strength between the second-1 inorganic encapsulation layer 331 and the organic encapsulation layer 320 may be 1.76 gf/inch, for example.

In addition, because the second-1 inorganic encapsulation layer 331 and the second-2 inorganic encapsulation layer 332 are both inorganic layers, the adhesive strength between the second-1 inorganic encapsulation layer 331 and the second-2 inorganic encapsulation layer 332 is substantially high compared to the adhesive strength between the first inorganic encapsulation layer 310 and the organic encapsulation layer 320, which is the adhesive strength between the organic layer and the inorganic layer. Therefore, when the compressive stress of the second-2 inorganic encapsulation layer 332 is relatively large and the compressive stress applied per unit area of the display apparatus 10 becomes excessively large, separation occurs between the first inorganic encapsulation layer 310 and the organic encapsulation layer 320 with relatively low adhesive strength therebetween.

When the ratio of nitrogen (N) to silicon (Si) in the second-2 inorganic encapsulation layer 332 is less than 0.75, the second-2 inorganic encapsulation layer 332 may have a compressive stress of less than 50 MPa. However, when the ratio of nitrogen (N) to silicon (Si) in the second-2 inorganic encapsulation layer 332 is less than 0.75, the second-2 inorganic encapsulation layer 332 may be too porous and may not sufficiently seal the display element DPE. Therefore, moisture or oxygen from the outside may easily penetrate into the inside of the display apparatus 10.

Table 1 shows the ratio (N/Si) of nitrogen (N) to silicon (Si) in the second-2 inorganic encapsulation layer 332 of each of Comparative Example 1, Comparative Example 2, and Embodiments 1 to 3, the compressive stress of the second-2 inorganic encapsulation layer 332, the separation of the organic encapsulation layer 320, and the water vapor transmission rate (“WVTR”) of the second-2 inorganic encapsulation layer 332. Comparative Example 1, Comparative Example 2, and Embodiments 1 to 3 are different only in the second-2 inorganic encapsulation layer 332, and remaining (the other) components except for the second-2 inorganic encapsulation layer 332 are the same therebetween.

The unit of the compressive stress is MPa, and the unit of the WVTR is g/m2·day. The WVTR of the second-2 inorganic encapsulation layer 332 has been evaluated by depositing an inorganic layer on a plastic film under the same conditions as the formation conditions of the second-2 inorganic encapsulation layer 332 and measuring the WVTR of the inorganic layer. ‘Separation of organic encapsulation layer’ in Table 1 indicates whether the organic encapsulation layer 320 is separated from the first inorganic encapsulation layer 310. When the organic encapsulation layer 320 is not separated from the first inorganic encapsulation layer 310, it is indicated as ‘X’ in Table 1, and when the organic encapsulation layer 320 is separated from the first inorganic encapsulation layer 310, it is indicated as ‘O’ in Table 1.

TABLE 1

| | | | Separation | Water vapor |
|---|---|---|---|---|
| | | Compressive | of organic | transmission |
| | | stress | encapsulation | rate (WVTR) |
| | N/Si | (MPa) | layer | (g/m² · day) |
| Comparative | 0.7 | 30 | X | 1 × 10⁻³ |
| Example 1 | | | | |
| Embodiment 1 | 0.75 | 50 | X | 1 × 10⁻⁴ |
| Embodiment 2 | 0.78 | 70 | X | 1 × 10⁻⁴ |
| Embodiment 3 | 0.8 | 90 | X | 1 × 10⁻⁴ |
| Comparative | 0.9 | 100 | ◯ | 1 × 10⁻⁴ |
| Example 2 | | | | |

Referring to Table 1, the ratio of nitrogen (N) to silicon (Si) in the second-2 inorganic encapsulation layer of Comparative Example 1 is less than 0.75. Specifically, the ratio of nitrogen (N) to silicon (Si) in the second-2 inorganic encapsulation layer of Comparative Example 1 is 0.7. Accordingly, the compressive stress of the second-2 inorganic encapsulation layer of Comparative Example 1 is less than 50 MPa. Specifically, the compressive stress of the second-2 inorganic encapsulation layer of Comparative Example 1 is 30 MPa. Therefore, in the case of Comparative Example 1, the organic encapsulation layer is not separated from the first inorganic encapsulation layer. However, the second-2 inorganic encapsulation layer of Comparative Example 1 has a WVTR of 1×10⁻³ g/m²·day. That is, the second-2 inorganic encapsulation layer of Comparative Example 1 does not sufficiently block moisture or oxygen from the outside.

The ratio of nitrogen (N) to silicon (Si) in the second-2 inorganic encapsulation layer of Comparative Example 2 is greater than 0.8. Specifically, the ratio of nitrogen (N) to silicon (Si) in the second-2 inorganic encapsulation layer of Comparative Example 2 is 0.9. Accordingly, the second-2 inorganic encapsulation layer of Comparative Example 2 has a WVTR of 1×10⁻⁴ g/m²·day. That is, the second-2 inorganic encapsulation layer of Comparative Example 2 may sufficiently block moisture or oxygen from the outside. However, the compressive stress of the second-2 inorganic encapsulation layer of Comparative Example 2 is greater than 90 MPa. Specifically, the compressive stress of the second-2 inorganic encapsulation layer of Comparative Example 2 is 100 MPa. Accordingly, in the case of Comparative Example 2, the organic encapsulation layer is separated from the first inorganic encapsulation layer.

The ratio of nitrogen (N) to silicon (Si) in the second-2 inorganic encapsulation layer 332 of each of Embodiments 1 to 3 is about 0.75 to about 0.8. Specifically, the ratio of nitrogen (N) to silicon (Si) in the second-2 inorganic encapsulation layer 332 of Embodiment 1 is 0.75, the ratio of nitrogen (N) to silicon (Si) in the second-2 inorganic encapsulation layer 332 of Embodiment 2 is 0.78, and the ratio of nitrogen (N) to silicon (Si) in the second-2 inorganic encapsulation layer 332 of Embodiment 3 is 0.8.

Accordingly, the compressive stress of the second-2 inorganic encapsulation layer 332 of each of Embodiments 1 to 3 is about 50 MPa to about 90 MPa. Specifically, the compressive stress of the second-2 inorganic encapsulation layer 332 of Embodiment 1 is 50 MPa, the compressive stress of the second-2 inorganic encapsulation layer 332 of Embodiment 2 is 70 MPa, and the compressive stress of the second-2 inorganic encapsulation layer 332 of Embodiment 3 is 90 MPa. Accordingly, in the cases of Embodiments 1 to 3, the organic encapsulation layer 320 is not separated from the first inorganic encapsulation layer 310. In addition, the second-2 inorganic encapsulation layer 332 of each of Embodiments 1 to 3 has a WVTR of 1×10⁻⁴ g/m²·day. That is, the second-2 inorganic encapsulation layer 332 of each of Embodiments 1 to 3 may sufficiently block moisture or oxygen from the outside.

Up to now, the display apparatus 10 has been described, but the disclosure is not limited thereto. A method of manufacturing the display apparatus 10 is also within the scope of the disclosure. Hereinafter, the method of manufacturing the display apparatus 10 will be described.

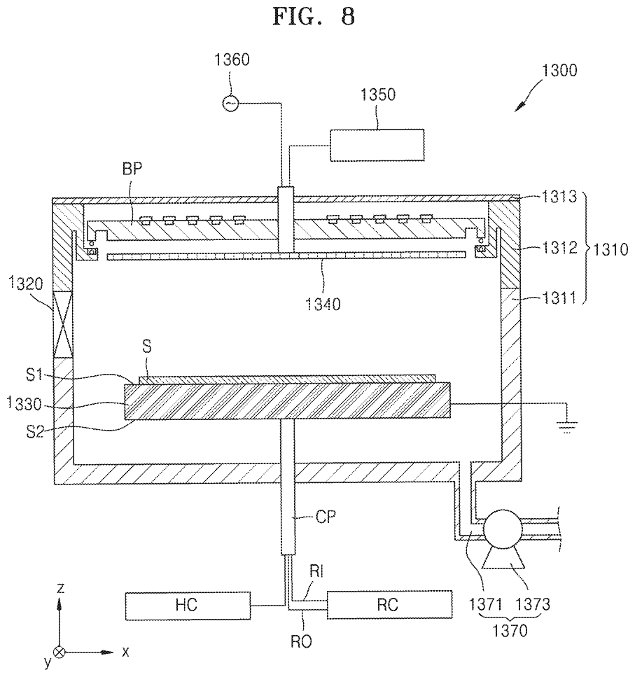

FIG. 8 is a cross-sectional view schematically illustrating a manufacturing apparatus 1300 for a display apparatus, which is used in a process of manufacturing the display apparatus 10 of FIG. 7. The manufacturing apparatus 1300 for a display apparatus may form a component included in the display apparatus 10. In an embodiment, the manufacturing apparatus 1300 for a display apparatus may form a silicon-based insulating layer included in the display apparatus 10, for example. In FIG. 8, a display substrate S is illustrated together with the manufacturing apparatus 1300 for convenience of description. The display substrate S may be a display apparatus under manufacturing. That is, the display substrate S may be a display apparatus under manufacturing, on which a process prior to the process of forming the silicon-based insulating layer has been performed.

The manufacturing apparatus 1300 for a display apparatus may include a CVD apparatus or a plasma enhanced chemical vapor deposition (“PECVD”) apparatus. As illustrated in FIG. 8, the manufacturing apparatus 1300 for a display apparatus may include a chamber 1310, an opening/closing portion 1320, a susceptor 1330, a sprayer 1340, a deposition material supplier 1350, a power supplier 1360, a pressure controller 1370, a driver CP, a heater controller HC, and a refrigerant controller RC.

The chamber 1310 may have a space formed therein, and may be formed such that one side is opened so that the display substrate S may be withdrawn or stored therein. In other words, the chamber 1310 may have a space therein, and the display substrate S may be withdrawn from or stored in the space. In an embodiment, the opening/closing portion 1320 including a gate valve may be disposed in an open portion of the chamber 1310 so that the opening/closing portion 1320 may be selectively opened/closed. When the opening/closing portion 1320 is opened, the display substrate S may be loaded into the chamber 1310.

The chamber 1310 may include a first part 1311, a second part 1312, and a third part 1313. The first part 1311 may correspond to a chamber body. The second part 1312 may be disposed above the first part 1311. The second part 1312 may correspond to a lid. The third part 1313 may correspond to a cover plate. The third part 1313 may be disposed to cover a backing plate BP. In this case, the backing plate BP may protect the inside of the chamber 1310 from the atmospheric environment and prevent a deposition material sprayed from the sprayer 1340 from leaking out. In an embodiment, a plurality of refrigerant paths may be arranged in the backing plate BP.

The display substrate S may be disposed (e.g., mounted) on the susceptor 1330 disposed inside the chamber 1310. In other words, the susceptor 1330 may be accommodated inside the chamber 1310, and the display substrate S may be disposed (e.g., mounted) on the susceptor 1330. Specifically, the susceptor 1330 may include a first surface S1 facing the sprayer 1340 and a second surface S2 facing away from the sprayer 1340. The display substrate S may be disposed on the first surface S1 of the susceptor 1330. That is, the susceptor 1330 may support the display substrate S.

In an embodiment, the center of the susceptor 1330 may protrude in the +z direction more than the edge of the susceptor 1330. The display substrate S may be disposed (e.g., mounted) on the center of the susceptor 1330. However, the disclosure is not limited thereto. In this case, the center of the susceptor 1330 may be provided integrally with the edge of the susceptor 1330.

The susceptor 1330 may include at least one of aluminum (Al), magnesium (Mg), zinc (Zn), manganese (Mn), and copper (Cu). In an embodiment, the susceptor 1330 may include aluminum (Al), for example. In an alternative embodiment, the susceptor 1330 may include an aluminum (Al)-zinc (Zn)-magnesium (Mg) alloy.

The driver CP may be disposed below the susceptor 1330. The driver CP may adjust the position of the susceptor 1330. Accordingly, the susceptor 1330 may be raised or lowered. In an embodiment, the driver CP may include a cylinder, for example. In an alternative embodiment, the driver CP may include a linear motor. In an alternative embodiment, the driver CP may include a rack and pinion. However, the disclosure is not limited thereto, and the driver CP may include all apparatuses and all structures that control the position of the susceptor 1330.

The susceptor 1330 may control the temperature of the disposed (e.g., mounted) display substrate S. In an embodiment, the susceptor 1330 may include a path through which a refrigerant circulates and/or a heater, for example. That is, a refrigerant such as cooling water may circulate through the path through which the refrigerant circulates in the susceptor 1330, or the heater of the susceptor 1330 may generate heat, thereby controlling the temperature of the display substrate S disposed (e.g., mounted) on the susceptor 1330. Because the susceptor 1330 includes the path through which the refrigerant circulates and/or the heater, the susceptor 1330 may satisfy various process conditions.

A heater wire connected to the heater of the susceptor 1330 may pass through the inside of the driver CP and may be connected to the heater controller HC. In addition, a refrigerant inlet RI and a refrigerant outlet RO, connected to the path through which the refrigerant circulates in the susceptor 1330, may pass through the inside of the driver CP and be connected to the refrigerant controller RC.

The heater controller HC may be connected to the heater of the susceptor 1330 and control the temperature of the heater. The refrigerant controller RC may be connected to the path of the susceptor 1330 and control the temperature of the refrigerant. The refrigerant controller RC may supply, through the refrigerant inlet RI, the refrigerant to the path through which the refrigerant circulates in the susceptor 1330. In addition, the refrigerant controller RC may receive, through the refrigerant outlet RO, the refrigerant circulated through the path. The refrigerant may include perfluoropolyether (“PFPE”). In an embodiment, the refrigerant may be a Galden® solution, for example.

The sprayer 1340 may supply a deposition material into the chamber 1310. The sprayer 1340 may have a plurality of nozzles, and the deposition material may be sprayed into the chamber 1310 through the plurality of nozzles. The deposition material may be a gas including or consisting of a component that becomes a raw material for a layer to be formed on the display substrate S. In an embodiment, the deposition material may be a gas including or consisting of a component that becomes a raw material for a silicon-based insulating layer, that is, silicon (Si), oxygen (O), or nitrogen (N), for example.

In an embodiment, the sprayer 1340 may function as one of two electrodes for forming plasma together with the susceptor 1330. In an embodiment, the sprayer 1340 may be connected to the power supplier 1360, for example. The susceptor 1330 may be grounded. Accordingly, when the sprayer 1340 sprays the deposition material, plasma may be formed between the sprayer 1340 and the susceptor 1330. The deposition material may form radicals as the deposition material passes through a region where the plasma is formed, and the radicals may react on the display substrate S to form a silicon-based insulating layer. That is, the deposition process for the silicon-based insulating layer may be performed using plasma.

The deposition material supplier 1350 may supply the deposition material to the sprayer 1340. In addition, the deposition material supplier 1350 may store the deposition material.

The power supplier 1360 may be electrically connected to the sprayer 1340. In an embodiment, the power supplier 1360 may supply AC power to the sprayer 1340. In this case, the sprayer 1340 may function as an upper electrode, and the susceptor 1330 may function as a lower electrode. Accordingly, plasma may be formed between the sprayer 1340 and the susceptor 1330.

The pressure controller 1370 may include a connecting pipe 1371 connected to the chamber 1310 and a pump 1373 installed in the connecting pipe 1371. In this case, depending on the operation of the pump 1373, outside air may be introduced through the connecting pipe 1371, or gas inside the chamber 1310 may be guided to the outside through the connecting pipe 1371.

Although not shown in the drawings, the manufacturing apparatus 1300 for a display apparatus may further include a mask frame. In this case, the mask frame may be placed between the susceptor 1330 and the sprayer 1340. In an embodiment, the mask frame may be fixed inside the chamber 1310. The mask frame may shield the edge of the display substrate S. Accordingly, the mask frame may prevent the deposition material sprayed from the sprayer 1340 from being deposited on the edge of the display substrate S.

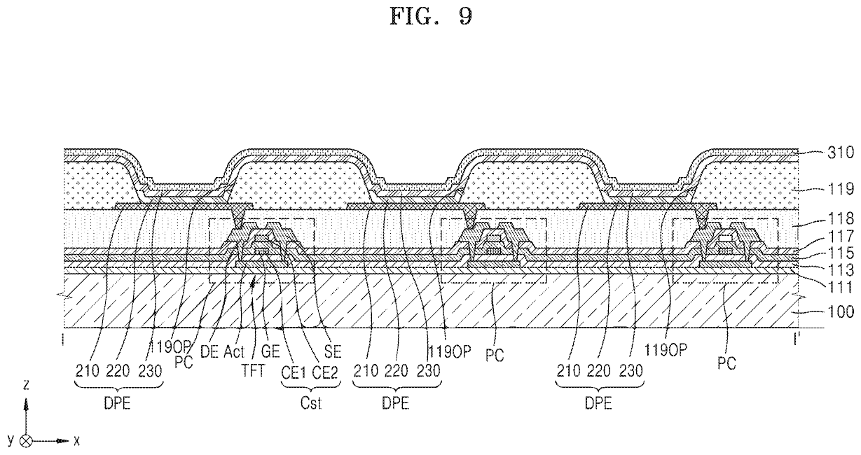

FIGS. 9 to 12 are cross-sectional views schematically illustrating a part of a process of manufacturing the display apparatus 10 of FIG. 7. Specifically, FIGS. 9 to 12 are cross-sectional views schematically illustrating a process of manufacturing the first inorganic encapsulation layer 310, the organic encapsulation layer 320, the second-1 inorganic encapsulation layer 331, and the second-2 inorganic encapsulation layer 332 of the display apparatus 10 of FIG. 7. In FIGS. 9 to 12, for convenience of description, a method of manufacturing a display apparatus will be described based on the cross-section of the display apparatus 10 taken along line I-I′ of FIG. 2. Hereinafter, in describing a method of manufacturing a display apparatus, in an embodiment, with reference to FIGS. 9 to 12, the same reference numerals as those in FIG. 7 indicate the same components as those in FIG. 7, and thus, duplicate descriptions are omitted.

First, as illustrated in FIG. 9, a first inorganic encapsulation layer 310 may be formed on a substrate 100. A display element DPE and a pixel circuit PC may be arranged on the substrate 100. Specifically, before the forming of the first inorganic encapsulation layer 310 on the substrate 100, a buffer layer 111 may be formed on the substrate 100, and a semiconductor layer Act may be formed on the buffer layer 111. Next, a gate insulating layer 113 may be formed on the semiconductor layer Act, and a gate electrode GE may be formed on the gate insulating layer 113. Next, a first inter-insulating layer 115 may be formed on the gate electrode GE, and a second capacitor electrode CE2 may be formed on the first inter-insulating layer 115. Next, a second inter-insulating layer 117 may be formed on the second capacitor electrode CE2, and a source electrode SE and a drain electrode DE may be formed on the second inter-insulating layer 117.

Next, an organic insulating layer 118 may be formed on the source electrode SE and the drain electrode DE, and a pixel electrode 210 may be formed on the organic insulating layer 118. Next, a pixel-defining layer 119 defining a pixel opening 119OP may be formed to cover an edge of the pixel electrode 210, an emission layer 220 may be formed on the pixel electrode 210 and the pixel-defining layer 119, and an opposite electrode 230 may be formed on the emission layer 220 and the pixel-defining layer 119. That is, the display element DPE and the pixel circuit PC may be formed on the substrate 100. The display element DPE may include the pixel electrode 210, the emission layer 220, and the opposite electrode 230, and the pixel circuit PC may include a transistor TFT and a storage capacitor Cst. The transistor TFT may include the semiconductor layer Act, the gate electrode GE, the source electrode SE, and the drain electrode DE, and the storage capacitor Cst may include the first capacitor electrode CE1 and the second capacitor electrode CE2.

In other words, before the forming of the first inorganic encapsulation layer 310 on the substrate 100, the display element DPE and the pixel circuit PC described above with reference to FIG. 7 are formed on the substrate 100. The first inorganic encapsulation layer 310 may be formed on the display element DPE. That is, the first inorganic encapsulation layer 310 may be formed on the substrate 100 on which the display element DPE is disposed. Because the formation of the display element DPE, the pixel circuit PC, or the like is a general matter in the manufacture of the display apparatus, a detailed description thereof is be omitted.

The first inorganic encapsulation layer 310 formed on the substrate 100 may have a relatively small surface roughness, and the adhesive strength between the first inorganic encapsulation layer 310 and the organic encapsulation layer 320 may be low. The surface roughness may be about 2 nm to about 6 nm based on the arithmetic mean roughness. In an embodiment, the surface roughness of the first inorganic encapsulation layer 310 may be 4 nm based on the arithmetic mean roughness, for example. Accordingly, the adhesive strength between the first inorganic encapsulation layer 310 and the organic encapsulation layer 320 may be about 1.1 gf/inch to about 1.2 gf/inch. In an embodiment, the adhesive strength between the first inorganic encapsulation layer 310 and the organic encapsulation layer 320 may be 1.17 gf/inch, for example. The adhesive strength between the first inorganic encapsulation layer 310 and the organic encapsulation layer 320 may be less than the adhesive strength between the second-1 inorganic encapsulation layer 331 and the organic encapsulation layer 320.

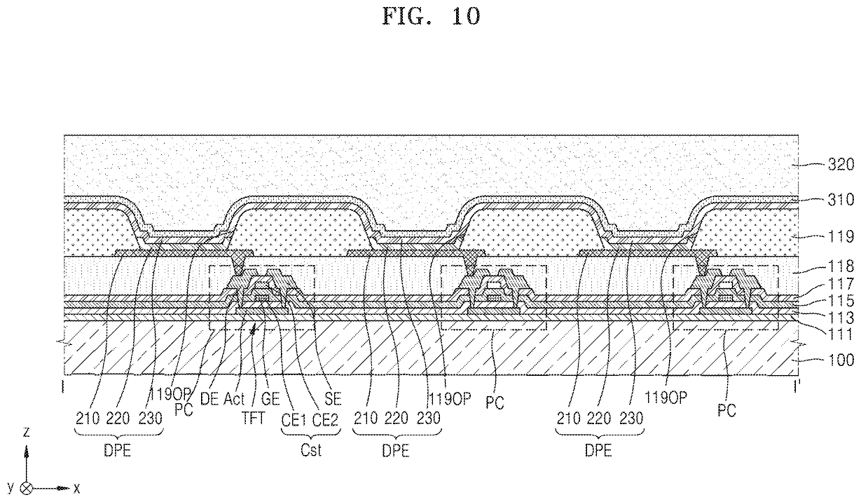

Next, as illustrated in FIG. 10, the organic encapsulation layer 320 may be formed on the first inorganic encapsulation layer 310. That is, the organic encapsulation layer 320 may be formed directly on the first inorganic encapsulation layer 310. Specifically, the organic encapsulation layer 320 may be formed by applying an organic encapsulation layer forming material on the first inorganic encapsulation layer 310 and curing the organic encapsulation layer forming material. In an embodiment, the organic encapsulation layer 320 may be formed by applying an organic encapsulation layer forming material on the first inorganic encapsulation layer 310 through inkjet printing and then curing the organic encapsulation layer forming material by heat or light, for example.

Any organic encapsulation layer forming material may be used as the organic encapsulation layer forming material of the disclosure as long as it is a material available for forming the organic encapsulation layer 320, and is not particularly limited. In an embodiment, the organic encapsulation layer forming material may include one or more materials selected from the group including or consisting of polyethyleneterephthalate, polyethylenenaphthalate, polycarbonate, polyimide, polyethylenesulfonate, polyoxymethylene, polyarylate, and hexamethyldisiloxane through curing, for example.

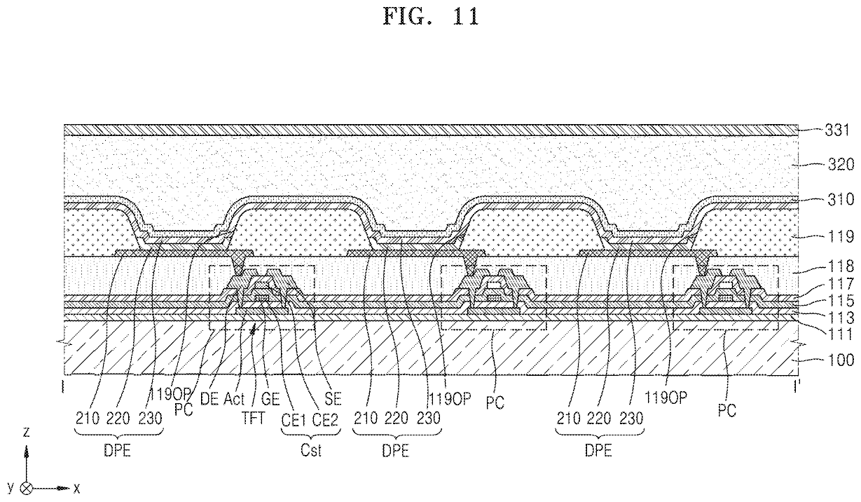

Then, as illustrated in FIG. 11, the second-1 inorganic encapsulation layer 331 may be formed on the organic encapsulation layer 320. That is, the second-1 inorganic encapsulation layer 331 may be formed directly on the organic encapsulation layer 320. Specifically, the second-1 inorganic encapsulation layer 331 may be formed on the organic encapsulation layer 320 by a method such as chemical vapor deposition, and to this end, the manufacturing apparatus 1300 for a display apparatus, described above with reference to FIG. 8, may be used.

The ratio of nitrogen (N) to silicon (Si) in the second-1 inorganic encapsulation layer 331 may be less than the ratio of nitrogen (N) to silicon (Si) in the second-2 inorganic encapsulation layer 332. Specifically, the ratio of nitrogen (N) to silicon (Si) in the second-1 inorganic encapsulation layer 331 may be about 0.65 to about 0.7. In an embodiment, the ratio of nitrogen (N) to silicon (Si) in the second-1 inorganic encapsulation layer 331 may be 0.67, for example. Accordingly, the density of the second-1 inorganic encapsulation layer 331 may be lower than the density of the second-2 inorganic encapsulation layer 332. The thickness (TH1 of FIG. 7) of the second-1 inorganic encapsulation layer 331 may be about 500 Å to about 1,000 Å.

Unlike the first inorganic encapsulation layer 310 having a relatively small surface roughness, which results in relatively low adhesive strength between the first inorganic encapsulation layer 310 and the organic encapsulation layer 320, the adhesive strength between the second-1 inorganic encapsulation layer 331 and the organic encapsulation layer 320 may be sufficiently high. Specifically, the adhesive strength between the second-1 inorganic encapsulation layer 331 and the organic encapsulation layer 320 may be about 1.7 gf/inch to about 1.8 gf/inch. In an embodiment, the adhesive strength between the second-1 inorganic encapsulation layer 331 and the organic encapsulation layer 320 may be 1.76 gf/inch, for example.

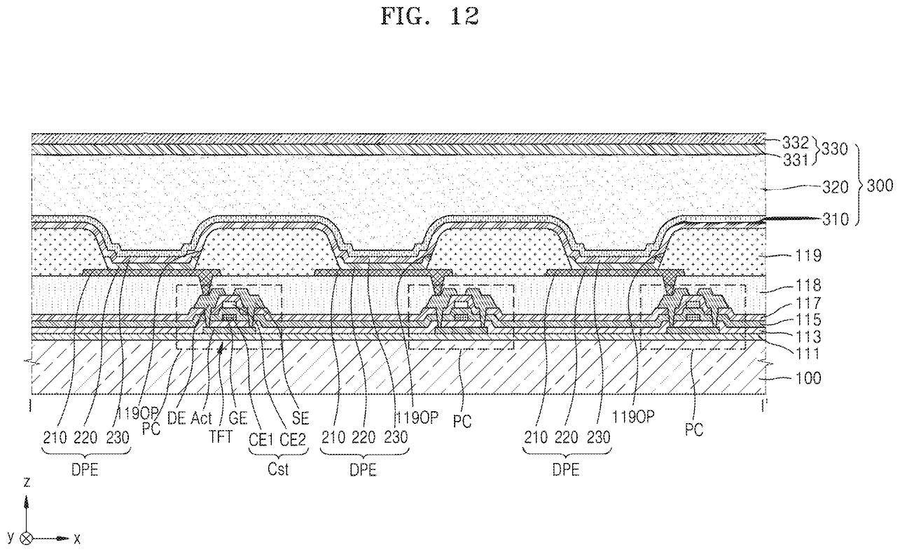

Next, as illustrated in FIG. 12, the second-2 inorganic encapsulation layer 332 may be formed on the second-1 inorganic encapsulation layer 331. Specifically, the second-2 inorganic encapsulation layer 332 may be formed on the second-1 inorganic encapsulation layer 331 through a method such as chemical vapor deposition, and to this end, the manufacturing apparatus 1300 for a display apparatus, described above with reference to FIG. 8 may be used.

In an embodiment, the display substrate S of FIG. 8 may be a display apparatus under manufacturing, in which the second-1 inorganic encapsulation layer 331 has been formed, for example. The display substrate S may be placed on the susceptor 1330, and a first gas including silane (SiH₄) gas and ammonia (NH₃) gas may be supplied into the chamber 1310 by the sprayer 1340. In other words, the first gas including silane (SiH₄) gas and ammonia (NH₃) gas may be used to form the second-2 inorganic encapsulation layer 332.

When a layer including or consisting of silicon nitride (SiN_{X}) is formed by a method such as chemical vapor deposition, deposition conditions during the chemical vapor deposition may affect the residual stress of the layer including or consisting of silicon nitride (SiN_{X}). In an embodiment, the composition ratio of the deposition material, the distance between the sprayer 1340 and the susceptor 1330, the power supplied by the power supplier 1360, and the pressure inside the chamber 1310 may affect the residual stress of the layer including or consisting of silicon nitride (SiN_{X}), for example. However, the composition ratio of the deposition material has the greatest effect on the residual stress of the layer including or consisting of silicon nitride (SiN_{X}), and the distance between the sprayer 1340 and the susceptor 1330, the power supplied by the power supplier 1360, and the pressure inside the chamber 1310 have minimal effects on the residual stress of the layer including or consisting of silicon nitride (SiN_{X}).

That is, the volume ratio between the silane (SiH₄) gas and the ammonia (NH₃) gas included in the first gas may have the greatest effect on the residual stress of the second-2 inorganic encapsulation layer 332. In other words, the ratio of the flow rate of the ammonia (NH₃) gas to the flow rate of the silane (SiH₄) gas in the first gas may have the greatest effect on the residual stress of the second-2 inorganic encapsulation layer 332. In the specification, the ratio of the flow rate of the ammonia (NH₃) gas to the flow rate of the silane (SiH₄) gas in the first gas refers to the ratio of the flow rate of ammonia (NH₃) gas of the first gas to the flow rate of silane (SiH₄) gas of the first gas. In other words, the ratio of the flow rate of the ammonia (NH₃) gas to the flow rate of the silane (SiH₄) gas in the first gas refers to the flow rate of ammonia (NH₃) gas when the flow rate of silane (SiH₄) gas is 1.

In an embodiment, the ratio of the flow rate of the ammonia (NH₃) gas to the flow rate of the silane (SiH₄) gas in the first gas may be about 0.5 to about 0.6. In this case, the ratio of nitrogen (N) to silicon (Si) in the second-2 inorganic encapsulation layer 332 may be about 0.75 to about 0.8. The thickness (TH2 of FIG. 7) of the second-2 inorganic encapsulation layer 332 may be about 3,000 Å to about 12,000 Å. Accordingly, the second-2 inorganic encapsulation layer 332 may have a compressive stress of about 50 MPa to about 90 MPa.

When the ratio of the flow rate of the ammonia (NH₃) gas to the flow rate of the silane (SiH₄) gas in the first gas exceeds 0.6, the ratio of nitrogen (N) to silicon (Si) in the second-2 inorganic encapsulation layer 332 may exceed 0.8. Accordingly, the second-2 inorganic encapsulation layer 332 may have a compressive stress exceeding 90 MPa. When the second-2 inorganic encapsulation layer 332 has a compressive stress exceeding 90 MPa, the compressive stress applied per unit area of the display apparatus 10 may be excessively large, and thus, the organic encapsulation layer 320 may be easily separated from the first inorganic encapsulation layer 310 during the process of manufacturing the display apparatus 10.

When the ratio of the flow rate of the ammonia (NH₃) gas to the flow rate of the silane (SiH₄) gas in the first gas is less than 0.5, the ratio of nitrogen (N) to silicon (Si) in the second-2 inorganic encapsulation layer 332 may be less than 0.75. Accordingly, the second-2 inorganic encapsulation layer 332 may have a compressive stress of less than 50 MPa. However, when the ratio of the flow rate of ammonia (NH₃) gas to the flow rate of silane (SiH₄) gas in the first gas is less than 0.5, the second-2 inorganic encapsulation layer 332 may be too porous and may not sufficiently seal the display element DPE. Therefore, moisture or oxygen from the outside may easily penetrate into the inside of the display apparatus 10.

Table 2 shows the ratio (N/Si) of nitrogen (N) to silicon (Si) in the second-2 inorganic encapsulation layer 332 of each of Comparative Example 1, Comparative Example 2, and Embodiments 1 to 3 of Table 1, and the ratio (NH₃/SiH₄) of the flow rate of ammonia (NH₃) gas to the flow rate of silane (SiH₄) gas in the first gas. In Comparative Example 1, Comparative Example 2, and Embodiments 1 to 3, only the ratio of the flow rate of ammonia (NH₃) gas to the flow rate of silane (SiH₄) gas in the first gas during the manufacture of the second-2 inorganic encapsulation layer 332 is different, and other conditions than the ratio of the flow rate of ammonia (NH₃) gas to the flow rate of silane (SiH₄) gas in the first gas are the same. Specifically, in Comparative Example 1, Comparative Example 2, and Embodiments 1 to 3, the distance between the sprayer 1340 and the susceptor 1330 is 990 mils, the power supplied by the power supplier 1360 is 7700 watts (W), and the pressure inside the chamber 1310 is 1500 millitorr (mTorr).

TABLE 2

| | N/Si | NH₃/SiH₄ |
|---|---|---|
| Comparative Example 1 | 0.7 | 0.4 |
| Embodiment 1 | 0.75 | 0.5 |
| Embodiment 2 | 0.78 | 0.54 |
| Embodiment 3 | 0.8 | 0.6 |
| Comparative Example 2 | 0.9 | 0.7 |

Referring to Table 2, the ratio of the flow rate of ammonia (NH₃) gas to the flow rate of silane (SiH₄) gas in the first gas during the manufacturing of the second-2 inorganic encapsulation layer of Comparative Example 1 is less than 0.5. Specifically, the ratio of the flow rate of ammonia (NH₃) gas to the flow rate of silane (SiH₄) gas in the first gas during the manufacturing of the second-2 inorganic encapsulation layer of Comparative Example 1 is 0.4. Accordingly, the ratio of nitrogen (N) to silicon (Si) in the second-2 inorganic encapsulation layer of Comparative Example 1 is 0.7, and the second-2 inorganic encapsulation layer of Comparative Example 1 has a WVTR of 1×10⁻³ g/m²·day. That is, the second-2 inorganic encapsulation layer of Comparative Example 1 does not sufficiently block moisture or oxygen from the outside.

The ratio of the flow rate of ammonia (NH₃) gas to the flow rate of silane (SiH₄) gas in the first gas during the manufacturing of the second-2 inorganic encapsulation layer of Comparative Example 2 is greater than 0.6. Specifically, the ratio of the flow rate of ammonia (NH₃) gas to the flow rate of silane (SiH₄) gas in the first gas during the manufacturing of the second-2 inorganic encapsulation layer of Comparative Example 2 is 0.7. Accordingly, the ratio of nitrogen (N) to silicon (Si) in the second-2 inorganic encapsulation layer of Comparative Example 2 is 0.9, and the compressive stress of the second-2 inorganic encapsulation layer of Comparative Example 2 is 100 MPa. Accordingly, in Comparative Example 2, the organic encapsulation layer is separated from the first inorganic encapsulation layer.

The ratio of the flow rate of ammonia (NH₃) gas to the flow rate of silane (SiH₄) gas in the first gas during the manufacturing of the second-2 inorganic encapsulation layer of each of Embodiments 1 to 3 is about 0.5 to about 0.6. Specifically, the ratio of the flow rate of ammonia (NH₃) gas to the flow rate of silane (SiH₄) gas in the first gas during the manufacturing of the second-2 inorganic encapsulation layer 332 of Embodiment 1 is 0.5, the ratio of the flow rate of ammonia (NH₃) gas to the flow rate of silane (SiH₄) gas in the first gas during the manufacturing of the second-2 inorganic encapsulation layer 332 of Embodiment 2 is 0.54, and the ratio of the flow rate of ammonia (NH₃) gas to the flow rate of silane (SiH₄) gas in the first gas during the manufacturing of the second-2 inorganic encapsulation layer 332 of Embodiment 3 is 0.6.

Accordingly, the compressive stress of the second-2 inorganic encapsulation layer 332 of Embodiment 1 is 50 MPa, the compressive stress of the second-2 inorganic encapsulation layer 332 of Embodiment 2 is 70 MPa, and the compressive stress of the second-2 inorganic encapsulation layer 332 of Embodiment 3 is 90 MPa. Therefore, in Embodiments 1 to 3, the organic encapsulation layer 320 is not separated from the first inorganic encapsulation layer 310. In addition, the second-2 inorganic encapsulation layer 332 of each of Embodiments 1 to 3 has a WVTR of 1×10⁻⁴ g/m²·day. That is, the second-2 inorganic encapsulation layer 332 of each of Embodiments 1 to 3 may sufficiently block moisture or oxygen from the outside.

By embodiments described above, a display apparatus having relatively low possibility of defect occurrence during a manufacturing process, a method of manufacturing the display apparatus, and an electronic apparatus may be implemented. However, the scope of the disclosure is not limited by these effects.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display apparatus comprising:
a substrate;
a display element disposed on the substrate; and
an encapsulation layer comprising:
a first inorganic encapsulation layer disposed on the display element;
a second inorganic encapsulation layer disposed on the first inorganic encapsulation layer, the second inorganic encapsulation layer comprising:
a second-1 inorganic encapsulation layer; and
a second-2 inorganic encapsulation layer; and
an organic encapsulation layer between the first inorganic encapsulation layer and the second inorganic encapsulation layer,
wherein the second-1 inorganic encapsulation layer is disposed on the organic encapsulation layer,
the second-2 inorganic encapsulation layer is disposed on the second-1 inorganic encapsulation layer, and
the second-2 inorganic encapsulation layer comprises silicon nitride, and a ratio of nitrogen to silicon in the second-2 inorganic encapsulation layer is about 0.75 to about 0.8.

2. The display apparatus of claim 1, wherein the second-2 inorganic encapsulation layer has a compressive stress of about 50 megapascals to about 90 megapascals.

3. The display apparatus of claim 1, wherein the second-1 inorganic encapsulation layer comprises silicon nitride, and a ratio of nitrogen to silicon in the second-1 inorganic encapsulation layer is less than the ratio of nitrogen to silicon in the second-2 inorganic encapsulation layer.

4. The display apparatus of claim 1, wherein a thickness of the second-1 inorganic encapsulation layer is about 500 angstroms to about 1,000 angstroms, and a thickness of the second-2 inorganic encapsulation layer is about 3,000 angstroms to about 12,000 angstroms.

5. The display apparatus of claim 1, wherein the first inorganic encapsulation layer is in direct contact with the organic encapsulation layer, the second-1 inorganic encapsulation layer is in direct contact with the organic encapsulation layer, and an adhesive strength between the first inorganic encapsulation layer and the organic encapsulation layer is less than an adhesive strength between the second-1 inorganic encapsulation layer and the organic encapsulation layer.

6. The display apparatus of claim 1, further comprising a touch sensor layer disposed on the encapsulation layer.

7. The display apparatus of claim 6, wherein the touch sensor layer comprises a touch conductive layer and a touch insulating layer covering the touch conductive layer.

8. A method of manufacturing a display apparatus, the method comprising:
forming a first inorganic encapsulation layer covering a display element on a substrate on which the display element is disposed;
forming an organic encapsulation layer on the first inorganic encapsulation layer;
forming a second-1 inorganic encapsulation layer on the organic encapsulation layer; and
forming, on the second-1 inorganic encapsulation layer, a second-2 inorganic encapsulation layer comprising silicon nitride,
wherein the forming the second-2 inorganic encapsulation layer comprises forming the second-2 inorganic encapsulation layer by a first gas comprising silane (SiH₄) gas and ammonia (NH₃) gas, and a ratio of a flow rate of the ammonia (NH₃) gas to a flow rate of the silane (SiH₄) gas in the first gas is about 0.5 to about 0.6.

9. The method of claim 8, wherein a ratio of nitrogen to silicon in the second-2 inorganic encapsulation layer is about 0.75 to about 0.8.

10. The method of claim 8, wherein the second-2 inorganic encapsulation layer has a compressive stress of about 50 megapascals to about 90 megapascals.

11. The method of claim 8, wherein a ratio of nitrogen to silicon in the second-1 inorganic encapsulation layer is less than a ratio of nitrogen to silicon in the second-2 inorganic encapsulation layer.

12. The method of claim 8, wherein a thickness of the second-1 inorganic encapsulation layer is about 500 angstroms to about 1,000 angstroms, and a thickness of the second-2 inorganic encapsulation layer is about 3,000 angstroms to about 12,000 angstroms.

13. The method of claim 8, wherein the forming the organic encapsulation layer comprises forming the organic encapsulation layer directly on the first inorganic encapsulation layer, and the forming the second-1 inorganic encapsulation layer comprises forming the second-1 inorganic encapsulation layer directly on the organic encapsulation layer,
wherein an adhesive strength between the first inorganic encapsulation layer and the organic encapsulation layer is less than an adhesive strength between the second-1 inorganic encapsulation layer and the organic encapsulation layer.

14. An electronic apparatus comprising:
a processor; and
a display apparatus controlled by the processor, the display apparatus comprising:
a substrate;
a display element disposed on the substrate; and
an encapsulation layer comprising:
a first inorganic encapsulation layer disposed on the display element;
a second inorganic encapsulation layer disposed on the first inorganic encapsulation layer, the second inorganic encapsulation layer comprising:
a second-1 inorganic encapsulation layer; and
a second-2 inorganic encapsulation layer; and
an organic encapsulation layer between the first inorganic encapsulation layer and the second inorganic encapsulation layer,
wherein the second-1 inorganic encapsulation layer is disposed on the organic encapsulation layer,
the second-2 inorganic encapsulation layer is disposed on the second-1 inorganic encapsulation layer, and
the second-2 inorganic encapsulation layer comprises silicon nitride, and a ratio of nitrogen to silicon in the second-2 inorganic encapsulation layer is about 0.75 to about 0.8.

15. The electronic apparatus of claim 14, wherein the second-2 inorganic encapsulation layer has a compressive stress of about 50 megapascals to about 90 megapascals.

16. The electronic apparatus of claim 14, wherein the second-1 inorganic encapsulation layer comprises silicon nitride, and a ratio of nitrogen to silicon in the second-1 inorganic encapsulation layer is less than the ratio of nitrogen to silicon in the second-2 inorganic encapsulation layer.

17. The electronic apparatus of claim 14, wherein a thickness of the second-1 inorganic encapsulation layer is about 500 angstroms to about 1,000 angstroms, and a thickness of the second-2 inorganic encapsulation layer is about 3,000 angstroms to about 12,000 angstroms.

18. The electronic apparatus of claim 14, wherein the first inorganic encapsulation layer is in direct contact with the organic encapsulation layer, the second-1 inorganic encapsulation layer is in direct contact with the organic encapsulation layer, and an adhesive strength between the first inorganic encapsulation layer and the organic encapsulation layer is less than an adhesive strength between the second-1 inorganic encapsulation layer and the organic encapsulation layer.

19. The electronic apparatus of claim 14, further comprising a touch sensor layer disposed on the encapsulation layer.

20. The electronic apparatus of claim 19, wherein the touch sensor layer comprises a touch conductive layer and a touch insulating layer covering the touch conductive layer.
